(19) United States
(12) Patent Application Publication
(10) Pub. No.: US 2013/0306962 A1
(43) Pub. Date: Nov. 21, 2013

(54) ORGANIC LIGHT EMITTING DEVICE AND MATERIALS FOR USE IN SAME

(71) Applicants: Hitoshi Yamamoto, Pennington, NJ (US); Michael S. Weaver, Princeton, NJ (US); Julia J. Brown, Yardley, PA (US); Kazuki Nishimura, Chiba (JP); Toshihiro Iwakuma, Chiba (JP); Kei Yoshida, Chiba (JP)

(72) Inventors: Hitoshi Yamamoto, Pennington, NJ (US); Michael S. Weaver, Princeton, NJ (US); Julia J. Brown, Yardley, PA (US); Kazuki Nishimura, Chiba (JP); Toshihiro Iwakuma, Chiba (JP); Kei Yoshida, Chiba (JP)

(73) Assignee: Universal Display Corporation, Ewing, NJ (US)

(21) Appl. No.: 13/995,276

(22) PCT Filed: Feb. 11, 2011
(86) PCT No.: PCT/US11/24553

§ 371 Date: Jun. 18, 2013

(51) Int. Cl. H01L 51/50

(52) U.S. Cl. CPC H01L 51/5028
USPC 257/40

(57) ABSTRACT

The OLEDs of the present invention are characterized by providing an organic thin film layer comprising a single layer or plural layers between a cathode and an anode, wherein the organic thin film layer comprises at least one organic light emitting layer, wherein at least one light emitting layer comprises at least one host material and at least one phosphorescent emitter material, wherein the host material comprises a substituted or unsubstituted hydrocarbon compound represented by the formula (1) or (2):

(Cz-)ₙA (1)

Cz(-A)ₘ (2)

wherein Cz represents a substituted or unsubstituted arylcarbazolyl group or carbazolylalkylene group, A represents a group represented by the following general formula (3):

(M)ₚ-(L)_{q}-(M′)ᵣ (3)

wherein M and M′ each independently represent a heteroaromatic ring having 2 to 40 carbon atoms and nitrogen atom and forming a substituted or unsubstituted ring, M and M′ may represent a same ring or different rings, L represents a single bond, a substituted or unsubstituted aryl group or arylene group having 6 to 30 carbon atoms, a substituted or unsubstituted cycloalkylene group having 5 to 30 carbon atoms or a substituted or unsubstituted heteroaromatic ring having 2 to 30 carbon atoms, p represents an integer of 0 to 2, q represents an integer of 1 or 2, r represents an integer of 0 to 2, and p+r represents an integer of 1 or greater; and n and m each represent an integer of 1 to 3;
and the phosphorescent emitter material comprises a phosphorescent organometallic complex having a substituted chemical structure represented by one of the following partial chemical structures represented by the formula:

LL′L″M

wherein M is a metal that forms octahedral complexes,
L, L′, L″ are equivalent or inequivalent bidentate ligands wherein each L comprises a substituted or unsubstituted phenylpyridine ligand coordinated to M through an sp2 hybridized carbon and N;
and one of L, L′ and L″ is inequivalent to at least one of the other two.

### BACKGROUND OF THE INVENTION

The present invention relates to an organic electroluminescent (EL) device such as an organic light emitting device (hereinafter abbreviated as an OLED) and materials capable of being used in such an OLED. In particular, it relates to an OLED which comprises a light emitting layer which emits a green light, and materials for an OLED which are used for the same.

### RELATED ART

OLEDs which comprise an organic thin film layer which includes a light emitting layer located between an anode and a cathode are known in the art. In such devices, emission of light may be obtained from exciton energy, produced by recombination of a hole injected into a light emitting layer with an electron.

Generally, OLEDs are comprised of several organic layers in which at least one of the layers can be made to electroluminesce by applying a voltage across the device (see, e.g., Tang, et al., Appl. Phys. Lett. 1987, 51, 913 and Burroughes, et al., Nature, 1990, 347, 359). When a voltage is applied across a device, the cathode effectively reduces the adjacent organic layers (i.e., injects electrons), and the anode effectively oxidizes the adjacent organic layers (i.e., injects holes). Holes and electrons migrate across the device toward their respective oppositely charged electrodes. When a hole and electron meet on the same molecule, recombination is said to occur, and an exciton is formed. Recombination of the hole and electron in luminescent compounds is accompanied by radiative emission, thereby producing electroluminescence.

Depending on the spin states of the hole and electron, the exciton resulting from hole and electron recombination can have either a triplet or singlet spin state. Luminescence from a singlet exciton results in fluorescence, whereas luminescence from a triplet exciton results in phosphorescence. Statistically, for organic materials typically used in OLEDs, one quarter of the excitons are singlets, and the remaining three-quarters are triplets (see, e.g., Baldo, et al., Phys. Rev. B, 1999, 60, 14422). Until the discovery that there were certain phosphorescent materials that could be used to fabricate practical electro-phosphorescent OLEDs (U.S. Pat. No. 6,303,238) and, subsequently, demonstration that such electro-phosphorescent OLEDs could have a theoretical quantum efficiency of up to 100% (i.e., harvesting all of both triplets and singlets), the most efficient OLEDs were typically based on materials that fluoresced. Fluorescent materials luminesce with a maximum theoretical quantum efficiency of only 25% (where quantum efficiency of an OLED refers to the efficiency with which holes and electrons recombine to produce luminescence), since the triplet to ground state transition of phosphorescent emission is formally a spin forbidden process. Electro-phosphorescent OLEDs have now been shown to have superior overall device efficiencies as compared with electro-fluorescent OLEDs (see, e.g., Baldo, et al., Nature, 1998, 395, 151 and Baldo, et al., Appl. Phys. Lett. 1999, 75(3), 4).

Due to strong spin-orbit coupling that leads to singlet-triplet state mixing, heavy metal complexes often display efficient phosphorescent emission from such triplets at room temperature. Accordingly, OLEDs comprising such complexes have been shown to have internal quantum efficiencies of more than 75% (Adachi, et al., Appl. Phys. Lett., 2000, 77, 904). Certain organometallic iridium complexes have been reported as having intense phosphorescence (Lamansky, et al., Inorganic Chemistry, 2001, 40, 1704), and efficient OLEDs emitting in the green to red spectrum have been prepared with these complexes (Lamansky, et al., J. Am. Chem. Soc., 2001, 123, 4304). Phosphorescent heavy metal organometallic complexes and their respective devices have been the subject of U.S. Pat. Nos. 6,830,828 and 6,902,830; U.S. Publications 2006/0202194 and 2006/0204785; and U.S. Pat. Nos. 7,001,536; 6,911,271; 6,939,624; and 6,835,469.

OLEDs, as described above, generally provide excellent luminous efficiency, image quality, power consumption and the ability to be incorporated into thin design products such as flat screens, and therefore hold many advantages over prior technology, such as cathode ray devices.

However, improved OLEDs, including, for example, the preparation of OLEDs having greater current efficiency are desirable. In this regard, light emitting materials (phosphorescent materials) have been developed in which light emission is obtained from a triplet exciton in order to enhance internal quantum efficiency.

As discussed above, such OLEDs can have a theoretical internal quantum efficiency up to 100% by using such phosphorescent materials in the light emitting layer (phosphorescent layer), and the resulting OLED will have a high efficiency and low power consumption. Such phosphorescent materials may be used as a dopant in a host material which comprises such a light emitting layer.

In a light emitting layer formed by doping with a light emitting material such as a phosphorescent material, excitons can efficiently be produced from a charge injected into a host material. Exciton energy of an exciton produced may be transferred to a dopant, and emission may be obtained from the dopant at high efficiency. Exitons may be formed either on the host materials or directly on the dopant.

In order to achieve intermolecular energy transfer from a host material to a phosphorescent dopant with high device efficiencies, the excited triplet energy EgH of the host material must be greater than the excited triplet energy EgD of the phosphorescent dopant.

In order to carry out intermolecular energy transfer from a host material to a phosphorescent dopant, an excited triplet energy Eg (T) of the host material has to be larger than an excited triplet energy Eg (S) of the phosphorescent dopant.

CBP (4,4′-bis(N-carbazolyl)biphenyl) is known to be a representative example of a material having an efficient and large excited triplet energy. See, e.g., U.S. Pat. No. 6,939,624. If CBP is used as a host material, energy can be transferred to a phosphorescent dopant having a prescribed emission wavelength, such as green, and an OLED having a high efficiency can be obtained. When CBP is used as a host material, the luminous efficiency is notably enhanced by phosphorescent emission. However, CBP is known to have a very short lifetime, and therefore it is not suitable for practical use in EL devices such as an OLED. Without being bound by scientific theory, it is believed that this is because CBP may be heavily deteriorated by a hole due to its oxidative stability not being high, in terms of molecular structure.

International Patent Application Publication WO 2005/112519 discloses a technique in which a condensed ring derivative having a nitrogen-containing ring such as carbazole and the like is used as a host material for a phosphorescent layer showing green phosphorescence. The current efficiency and the lifetime are improved by the above technique, but it is not satisfactory in a certain case for practical use.

On the other hand, a wide variety of host materials (fluorescent hosts) for a fluorescent dopant showing fluorescent emission are known, and various host materials can be proposed which, by combination with a fluorescent dopant, may form a fluorescent layer which exhibits excellent luminous efficiency and lifetime.

In a fluorescent host, an excited singlet energy Eg (S) is larger than in a fluorescent dopant, but an excited triplet energy Eg (T) of such a host is not necessarily larger. Accordingly, a fluorescent host cannot simply be used in place of a phosphorescent host as a host material to provide a phosphorescent emitting layer.

For example, anthracene derivatives are known well as a fluorescent host. However, an excited state triplet energy Eg (T) of anthracene derivatives may be as small as about 1.9 eV. Thus, energy transfer to a phosphorescent dopant having an emission wavelength in a visible light region of 500 nm to 720 nm cannot be achieved using such a host, since the excited state triplet energy would be quenched by a host having such a low triplet state energy. Accordingly, anthracene derivatives are unsuitable as a phosphorescent host.

Perylene derivatives, pyrene derivatives and naphthacene derivatives are not preferred as phosphorescent hosts for the same reason.

The use of aromatic hydrocarbon compounds as phosphorescent hosts is disclosed in Japanese Patent Application Laid-Open No. 142267/2003. That application discloses phosphorescent host compounds with a benzene skeleton core and with two aromatic substituents bonded at meta positions.

However, the aromatic hydrocarbon compounds described in Japanese Patent Application Laid-Open No. 142267/2003 assume a rigid molecular structure having a good symmetric property and provided with five aromatic rings in which molecules are arranged in a bilaterally symmetrical manner toward a central benzene skeleton. Such an arrangement has the drawback of a likelihood of crystallization of the light emitting layer.

On the other hand, OLEDs in which various aromatic hydrocarbon compounds are used are disclosed in International Patent Application Publications WO 2007/046685; Japanese Patent Application Laid-Open No. 151966/2006; Japanese Patent Application Laid-Open No. 8588/2005; Japanese Patent Application Laid-Open No. 19219/2005; Japanese Patent Application Laid-Open No. 19219/2005; and Japanese Patent Application Laid-Open No. 75567/2004. However, the efficiency of these materials as a phosphorescent host is not disclosed.

In addition, OLEDs prepared by using various fluorene compounds are disclosed in Japanese Patent Application Laid-Open No. 043349/2004; Japanese Patent Application Laid-Open No. 314506/2007; and Japanese Patent Application Laid-Open No. 042485/2004. However, the effectiveness of these materials as a phosphorescent host is not disclosed.

Further, Japanese Patent Application Laid-Open No. 042485/2004 discloses hydrocarbon compounds in which a condensed polycyclic aromatic ring is bonded directly to a fluorene ring. However, the effectiveness of an OLED prepared by combining such materials with a phosphorescent material is not disclosed, and the application discloses perylene and pyrene rings which are known to have a small triplet energy level as condensed polycyclic aromatic rings, and which are not preferred for use as a light emitting layer of a phosphorescent device, and materials which are effective for a phosphorescent device are not selected.

Despite the recent discoveries of efficient heavy metal phosphors and the resulting advancements in OLED technology, there remains a need for even greater high temperature device stability. In addition, there still remains a need for host materials which can transfer energy to a phosphorescent material with high efficiency and with an extended lifetime. Fabrication of devices that have longer high temperature lifetimes will contribute to the development of new display technologies and help realize the current goals toward full color electronic display on flat surfaces. The OLEDs and the host materials and phosphorescent emitter materials comprised in such OLEDs, described herein, help fulfill this objective.

### SUMMARY OF THE INVENTION

The OLEDs of the present invention are characterized by providing an organic thin film layer comprising a single layer or plural layers between a cathode and an anode, wherein the organic thin film layer comprises at least one organic light emitting layer, wherein at least one light emitting layer comprises at least one host material and at least one phosphorescent emitter material, wherein the host material comprises a substituted or unsubstituted hydrocarbon compound represented by the formula (1) or (2):

(Cz-)ₙA (1)

Cz(-A)ₘ (2)

wherein Cz represents a substituted or unsubstituted arylcarbazolyl group or carbazolylalkylene group, A represents a group represented by following the general formula (3):

(M)ₚ-(L)_{q}-(M′)ᵣ (3)

wherein M and M′ each independently represent a heteroaromatic ring having 2 to 40 carbon atoms and nitrogen atom and forming a substituted or unsubstituted ring, M and M′ may represent a same ring or different rings, L represents a single bond, a substituted or unsubstituted aryl group or arylene group having 6 to 30 carbon atoms, a substituted or unsubstituted cycloalkylene group having 5 to 30 carbon atoms or a substituted or unsubstituted heteroaromatic ring having 2 to 30 carbon atoms, p represents an integer of 0 to 2, q represents an integer of 1 or 2, r represents an integer of 0 to 2, and p+r represents an integer of 1 or greater; and n and m each represent an integer of 1 to 3.

In another embodiment, the OLED comprises a host material having the chemical structure represented by the formula (GH-1):

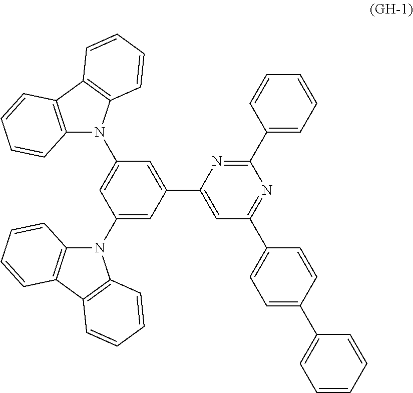 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

In one embodiment of the present invention, the phosphorescent emitter material comprises a phosphorescent organometallic complex having a substituted chemical structure represented by:

LL′L″M

wherein M is a metal that forms octahedral complexes,
L, L′, L″ are equivalent or inequivalent bidentate ligands wherein each L comprises a substituted or unsubstituted phenylpyridine ligand coordinated to M through an sp² hybridized carbon and N; and,

one of L, L′ and L″ is inequivalent to at least one of the other two.

In another embodiment, the phosphorescent emitter material comprises a phosphorescent organometallic compound having a substituted chemical structure represented by the following chemical structure (4):

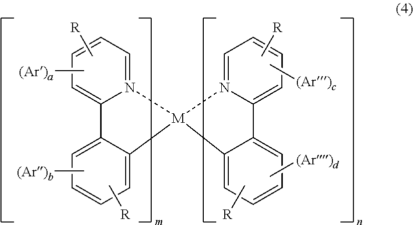

wherein each R is independently selected from the group consisting of H, alkyl, alkenyl, alkynyl, alkylaryl, CN, CF₃, CₙF₂ₙ₊₁, trifluorovinyl, CO₂R, C(O)R, NR₂, NO₂, OR, halo, aryl, heteroaryl, substituted aryl, substituted heteroaryl or a heterocylic group;

Ar′, Ar″, Ar′″ and Ar″″ each independently represent a substituted or unsubstituted aryl or heteroaryl unfused substituent on the phenylpyridine ligand;
a is 0 or 1; b is 0 or 1; c is 0 or 1; d is 0 or 1; m is 1 or 2; n is 1 or 2;
m+n is the maximum number of ligands that can be coordinated to M; and

wherein at least one of a, b, c, and d is 1 and when at least one of a and b is 1 and at least one of b and c is 1, at least one of Ar′ and Ar″ is different from at least one of Ar′″ and Ar″″.

In another embodiment, the phosphorescent emitter material comprises a metal complex, and the metal complex comprises a metal atom selected from Ir, Pt, Os, Au, Cu, Re and Ru and a ligand. In yet another embodiment the metal complex has an ortho-metal bond. In preferred embodiments, Ir is the metal atom.

In another embodiment, the phosphorescent emitter material comprises a phosphorescent organometallic complex having a substituted chemical structure represented by the following partial chemical structure (GD-1):

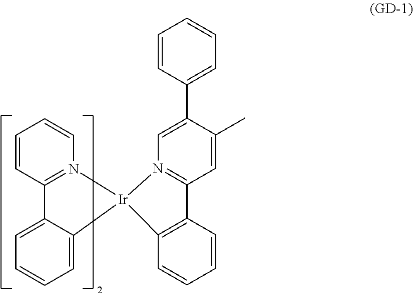

In another embodiment, the present invention comprises an OLED which comprises a host material which comprises an unsubstituted aromatic hydrocarbon compound having the chemical structure represented by the formula (GH-1):

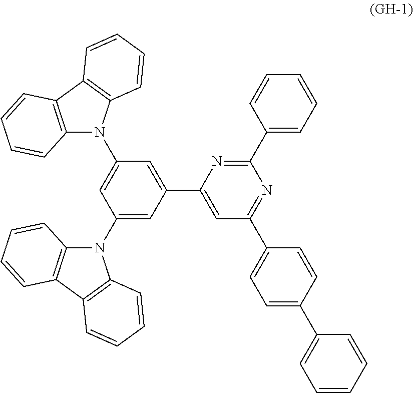 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

and a phosphorescent emitter material which comprises a phosphorescent organometallic compound having a substituted chemical structure represented by the following chemical structure:

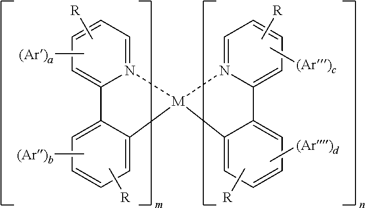

where each R is independently selected from the group consisting of H, alkyl, alkenyl, alkynyl, alkylaryl, CN, CF₃, CₙF₂ₙ₊₁, trifluorovinyl, CO₂R, C(O)R, NR₂, NO₂, OR, halo, aryl, heteroaryl, substituted aryl, substituted heteroaryl or a heterocylic group;

Ar′, Ar″, Ar′″ and Ar″″ each independently represent a substituted or unsubstituted aryl or heteroaryl unfused substituent on the phenylpyridine ligand;

a is 0 or 1; b is 0 or 1; c is 0 or 1; d is 0 or 1; m is 1 or 2; n is 1 or 2;
m+n is the maximum number of ligands that can be coordinated to M; and
wherein at least one of a, b, c, and d is 1 and when at least one of a and b is 1 and at least one of b and c is 1, at least one of Ar′ and Ar″ is different from at least one of Ar′″ and Ar″″.

In one embodiment, the present invention comprises an OLED which comprises a host material, wherein the triplet energy of the host material is from about 2.0 eV to about 2.8 eV.

In another embodiment, the present invention comprises an OLED which comprises at least one phosphorescent material in the light emitting layer, wherein the phosphorescent material has a maximum value of 500 nm or more and 720 nm or less in a light emitting wavelength.

In another embodiment, the present invention comprises an OLED which provides improved voltage and working lifetime characteristics. Without being bound by theory, it is believed that improved characteristics of the OLEDs of the present invention may be achieved due to the serial bonding of two or more condensed polycyclic aromatic rings to a monovalent fluorene skeleton and by bonding a group containing condensed polycyclic aromatic rings which are different from each other to a fluorene skeleton in a position in which a conjugate length is extended.

In another embodiment, the present invention comprises a phosphorescent OLED having high efficiency and long lifetime, which OLED comprises a material of general Formula (GH-1) as a host material, and particularly as a phosphorescent host material.

### BRIEF DESCRIPTION OF THE DRAWING

FIG. 1 is a drawing showing an outline constitution of one example of the OLED in the embodiment of the present invention.

### DETAILED DESCRIPTION

The OLEDs of the present invention may comprise a plurality of layers located between an anode and a cathode. Representative OLEDs according to the invention include, but are not limited to, structures having constituent layers as described below:

(1) Anode/light emitting layer/cathode;

(2) Anode/hole injecting layer/light emitting layer/cathode;

(3) Anode/light emitting layer/electron injecting•transporting layer/cathode;

(4) Anode/hole injecting layer/light emitting layer/electron injecting•transporting layer/cathode;

(5) Anode/organic semiconductor layer/light emitting layer/cathode;

(6) Anode/organic semiconductor layer/electron blocking layer/light emitting layer/cathode;

(7) Anode/organic semiconductor layer/light emitting layer/adhesion improving layer/cathode;

(8) Anode/hole injecting•transporting layer/light emitting layer/electron injecting•transporting layer/cathode;

(9) anode/insulating layer/light emitting layer/insulating layer/cathode;

(10) anode/inorganic semiconductor layer/insulating layer/light emitting layer/insulating layer/cathode;

(11) anode/organic semiconductor layer/insulating layer/light emitting layer/insulating layer/cathode;

(12) anode/insulating layer/hole injecting•transporting layer/light emitting layer/insulating layer/cathode; and

(13) anode/insulating layer/hole injecting•transporting layer/light emitting layer/electron injecting•transporting layer/cathode.

Among the OLED constituent structures described above, constituent structure number 8 is a preferred structure, but the present invention is not limited to these disclosed constituent structures.

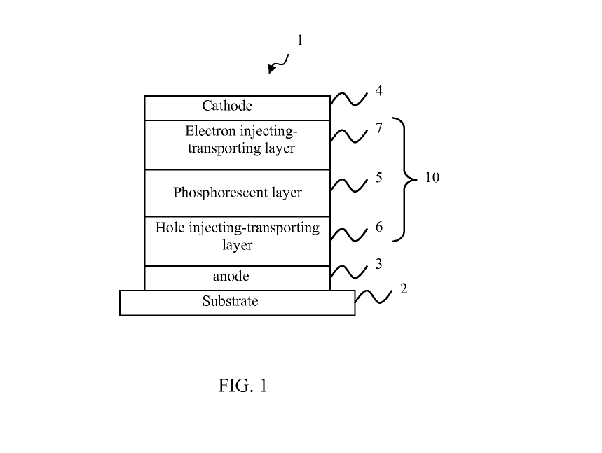

A schematic constitution of one example of an OLED in an embodiment of the present invention is shown in FIG. 1. As a representative embodiment of the invention, an OLED 1 comprises a transparent substrate 2, an anode 3, a cathode 4 and an organic thin film layer 10 disposed between the anode 3 and the cathode 4.

The organic thin film layer 10 comprises a phosphorescence emitting layer 5 containing a phosphorescent host and a phosphorescent dopant, and can provide respectively a hole injecting•transporting layer 6 and the like between the phosphorescence emitting layer 5 and the anode 3, and an electron injecting•transporting layer 7 and the like between the phosphorescence emitting layer 5 and the cathode 4.

Further, there may be provided respectively an electron blocking layer disposed between the anode 3 and the phosphorescence emitting layer 5, and a hole blocking layer disposed between the cathode 4 and the phosphorescence emitting layer 5. This makes it possible to contain electrons and holes in the phosphorescence emitting layer 5 to enhance the production rate of excitons in the phosphorescence emitting layer 5.

In the present specification, the terms “fluorescent host” and “phosphorescent host” are referred to as a fluorescent host when combined with a fluorescent dopant and as a phosphorescent host when combined with a phosphorescent dopant, respectively, and should not be limited to a classification of the host material based solely on molecular structure.

Accordingly, a fluorescent host in the present specification means a material constituting the fluorescence emitting layer containing a fluorescent dopant and does not mean a material which can be used only for a host of a fluorescent material.

Similarly, a phosphorescent host means a material constituting the phosphorescence emitting layer containing a phosphorescent dopant and does not mean a material which can be used only for a host of a phosphorescent material.

In the present specification, “a hole injecting•transporting layer” means at least either one of a hole injecting layer and a hole transporting layer, and “an electron injecting•transporting layer” means at least either one of an electron injecting layer and an electron transporting layer.

### Substrate

The OLED of the present invention may be prepared on a substrate. The substrate referred to in this case is a substrate for supporting the OLED, and it is preferably a flat substrate in which light in the visible region of about 400 to about 700 nm has a transmittance of at least about 50%.

The substrate may include a glass plate, a polymer plate and the like. In particular, the glass plate may include soda lime glass, barium•strontium-containing glass, lead glass, aluminosilicate glass, borosilicate glass, barium borosilicate glass, quartz and the like. The polymer plate may include polycarbonate, acryl, polyethylene terephthalate, polyether sulfide, polysulfone and the like.

### Anode and Cathode

An anode in the OLED of the present invention assumes the role of injecting a hole into the hole injecting layer, the hole transporting layer or the light emitting layer. Typically the anode has a work function of 4.5 eV or more.

Specific examples of a material suitable for use as the anode include indium tin oxide alloy (ITO), tin oxide (NESA), indium zinc oxide, gold, silver, platinum, copper and the like.

The anode can be prepared by forming a thin film from electrode substances, such as those discussed above, by a method such as a vapor deposition method, a sputtering method and the like.

When light is emitted from the light emitting layer, the transmittance of light in the visible light region in the anode is preferably larger than 10%. The sheet resistance of the anode is preferably several hundred Ω/square or less. The film thickness of the anode is selected, depending on the material, and is typically in the range of from about 10 nm to about 1 μm, and preferably from about 10 nm to about 200 nm.

The cathode comprises preferably a material having a small work function for the purpose of injecting an electron into the electron injecting layer, the electron transporting layer or the light emitting layer. Materials suitable for use as the cathode include, but are not limited to indium, aluminum, magnesium, magnesium-indium alloys, magnesium-aluminum alloys, aluminum-lithium alloys, aluminum-scandium-lithium alloys, magnesium-silver alloys and the like. For transparent or top-emitting devices, a TOLED cathode such as disclosed in U.S. Pat. No. 6,548,956 is preferred.

The cathode can be prepared, as is the case with the anode, by forming a thin film by a method such as a vapor deposition method, a sputtering method and the like. Further, an embodiment in which light emission is taken out from a cathode side can be employed as well.

### Light Emitting Layer

The light emitting layer in the OLED may be capable of carrying out the following functions singly or in combination:

(1) injecting function: a function in which a hole can be injected from an anode or a hole injecting layer in applying an electric field and in which an electron can be injected from a cathode or an electron injecting layer;

(2) transporting function: a function in which a charge (electron and hole) injected may be transferred by virtue of a force of an electric field; and

(3) light emitting function: a function in which a region for recombination of an electron and a hole may be provided, and which results in the emission of light.

A difference may be present between ease of injection of a hole and ease of injection of an electron, and a difference may be present in the transporting ability shown by the mobilities of a hole and an electron.

Known methods including, for example, vapor deposition, spin coating, Langmuir Blodgett methods and the like can be used to prepare the light emitting layer. The light emitting layer is preferably a molecularly deposited film. In this regard, the term “molecularly deposited film” means a thin film formed by depositing a compound from the gas phase and a film formed by solidifying a material compound in a solution state or a liquid phase state, and usually the above-referenced molecular deposit film can be distinguished from a thin film (molecular accumulation film) formed by an LB method by a difference in an aggregation structure and a higher order structure and a functional difference originating in it.

In preferred embodiments, the film thickness of the light emitting layer is preferably from about 5 to about 50 nm, more preferably from about 7 to about 50 nm and most preferably from about 10 to about 50 nm. If the film thickness is less than 5 nm, it is likely to be difficult to form the light emitting layer and control the chromaticity. On the other hand, if it exceeds about 50 nm, the operating voltage is likely to go up.

### OLEDs

In an OLED of the present invention, an organic thin film layer comprising one layer or plural layers is provided between a cathode and an anode; the above organic thin film layer comprises at least one light emitting layer; and at least one of the organic thin film layers contains at least one phosphorescent material and at least one host material as described below. Further, at least one of the light emitting layers contains preferably at least one host material of the present invention for an organic electroluminescence device and at least one phosphorescent material.

As described above, a phosphorescence emitting layer having high efficiency and long lifetime can be prepared according to the teachings of the present invention, especially a high stability at high operating temperatures.

In this regard, an excited triplet energy gap Eg(T) of the material constituting the OLED of the invention may be prescribed based on its phosphorescence emission spectrum, and it is given as an example in the present invention that the energy gap may be prescribed, as is commonly used, in the following manner.

The respective materials are dissolved in an EPA solvent (diethyl ether:isopentane:ethanol=5:5:2 in terms of a volume ratio) in a concentration of 10 μmol/L to prepare a sample for measuring phosphorescence. This phosphorescence measuring sample is placed in a quartz cell and cooled to 77 K, and is subsequently irradiated with exciting light to measure the wavelength of a phosphorescence emitted.

A tangent line is drawn based on the increase of phosphorescence emission spectrum thus obtained at the short wavelength side, and the wavelength value of the intersection point of the above tangent line and the base line is converted to an energy value, which is set as an excited triplet energy gap Eg(T). A commercially available measuring equipment F-4500 (manufactured by Hitachi, Ltd.) can be used for the measurement.

However, a value which can be defined as the triplet energy gap can be used without depending on the above procedure as long as it does not deviate from the scope of the present invention.

A preferred host material has the chemical structure represented by the formula (GH-1):

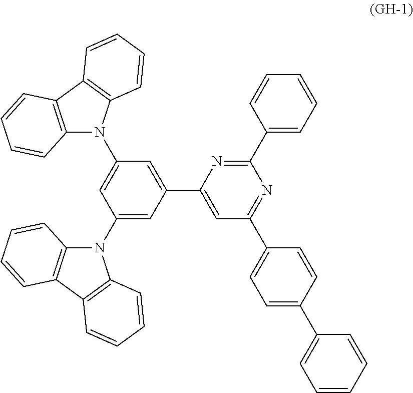 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

The materials of the present invention for an organic electroluminescence device have a large triplet energy gap Eg(T) (excited triplet energy), and therefore phosphorescent light can be emitted by transferring energy to a phosphorescent dopant.

In the present invention, the excited triplet energy of the host material described above is preferably from about 2.0 eV to about 2.8 eV. The excited triplet energy of about 2.0 eV or more makes it possible to transfer energy to a phosphorescent dopant material which emits light at a wavelength of 500 nm or more and 720 nm or less. The excited triplet energy of about 2.8 eV or less makes it possible to avoid the problem that light emission is not efficiently carried out in a green phosphorescent dopant because of the large difference in an energy gap. The excited triplet energy of the host material is more preferably from about 2.1 eV to about 2.7 eV.

Specific examples of suitable compounds for the host material according to the present invention, represented by the formulas (A1-115), include, but are not limited to, the following compounds:

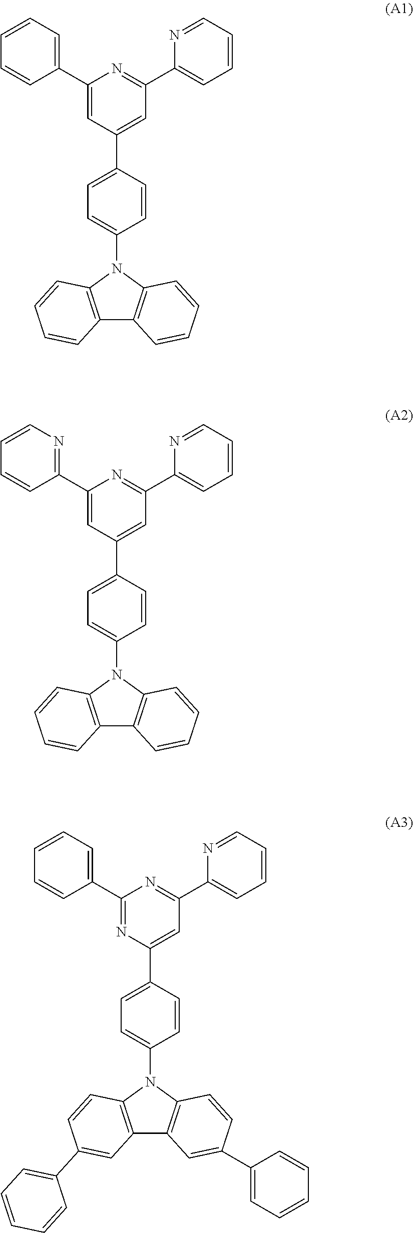 [SMILES: c1ccc(-c2cc(-c3ccc(-n4c5ccccc5c5ccccc54)cc3)cc(-c3ccccn3)n2)cc1 ; c1ccc(-c2cc(-c3ccc(-n4c5ccccc5c5ccccc54)cc3)cc(-c3ccccn3)n2)nc1 ; c1ccc(-c2ccc3c(c2)c2cc(-c4ccccc4)ccc2n3-c2ccc(-c3cc(-c4ccccn4)nc(-c4ccccc4)n3)cc2)cc1]

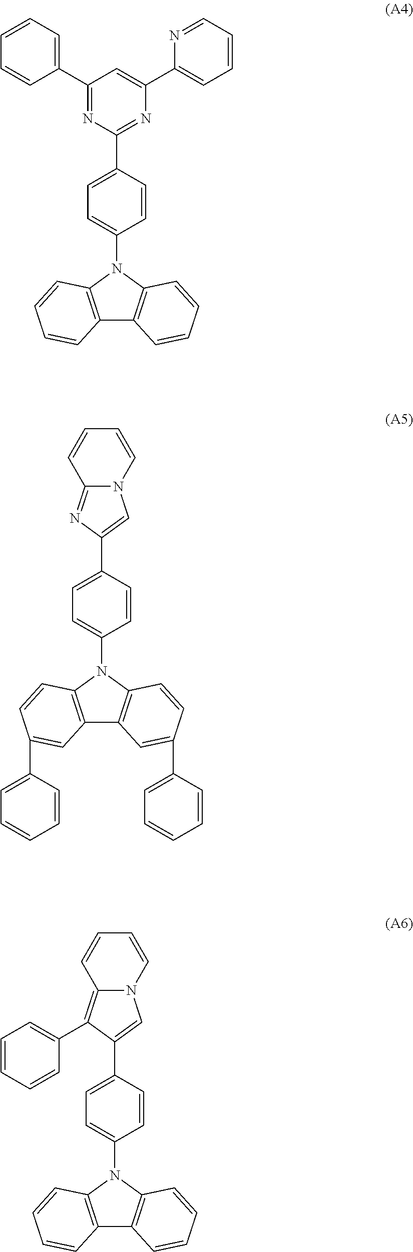 [SMILES: c1ccc(-c2cc(-c3ccccn3)nc(-c3ccc(-n4c5ccccc5c5ccccc54)cc3)n2)cc1 ; c1ccc(-c2ccc3c(c2)c2cc(-c4ccccc4)ccc2n3-c2ccc(-c3cn4ccccc4n3)cc2)cc1 ; c1ccc(-c2c(-c3ccc(-n4c5ccccc5c5ccccc54)cc3)cn3ccccc23)cc1]

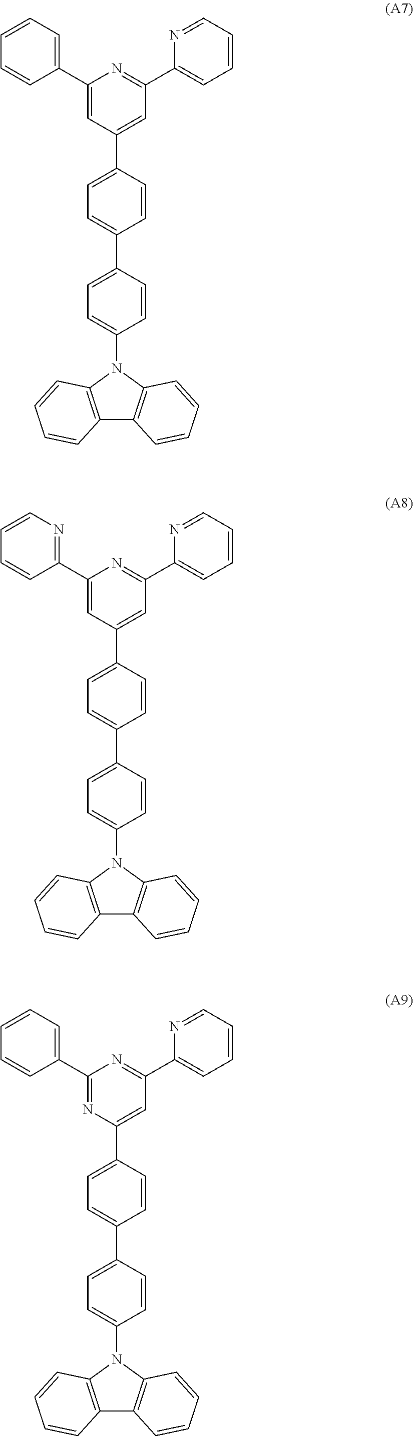 [SMILES: c1ccc(-c2cc(-c3ccc(-c4ccc(-n5c6ccccc6c6ccccc65)cc4)cc3)cc(-c3ccccn3)n2)cc1 ; c1ccc(-c2cc(-c3ccc(-c4ccc(-n5c6ccccc6c6ccccc65)cc4)cc3)cc(-c3ccccn3)n2)nc1 ; c1ccc(-c2nc(-c3ccc(-c4ccc(-n5c6ccccc6c6ccccc65)cc4)cc3)cc(-c3ccccn3)n2)cc1]

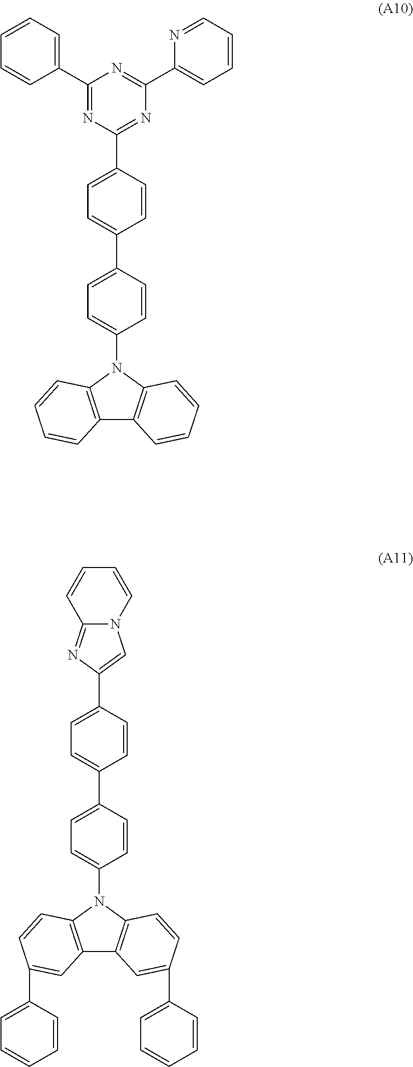 [SMILES: c1ccc(-c2nc(-c3ccc(-c4ccc(-n5c6ccccc6c6ccccc65)cc4)cc3)nc(-c3ccccn3)n2)cc1 ; c1ccc(-c2ccc3c(c2)c2cc(-c4ccccc4)ccc2n3-c2ccc(-c3ccc(-c4cn5ccccc5n4)cc3)cc2)cc1]

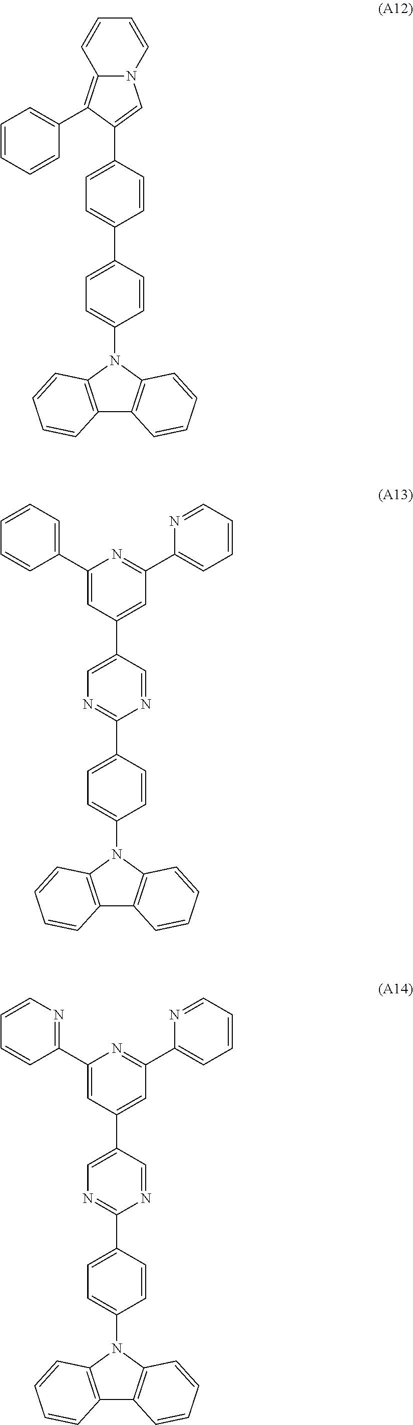 [SMILES: c1ccc(-c2c(-c3ccc(-c4ccc(-n5c6ccccc6c6ccccc65)cc4)cc3)cn3ccccc23)cc1 ; c1ccc(-c2cc(-c3cnc(-c4ccc(-n5c6ccccc6c6ccccc65)cc4)nc3)cc(-c3ccccn3)n2)cc1 ; c1ccc(-c2cc(-c3cnc(-c4ccc(-n5c6ccccc6c6ccccc65)cc4)nc3)cc(-c3ccccn3)n2)nc1]

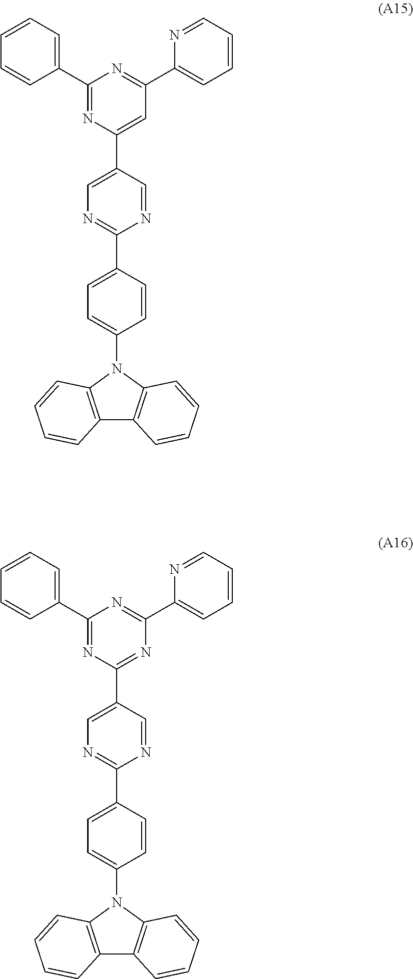 [SMILES: c1ccc(-c2nc(-c3cnc(-c4ccc(-n5c6ccccc6c6ccccc65)cc4)nc3)cc(-c3ccccn3)n2)cc1 ; c1ccc(-c2nc(-c3cnc(-c4ccc(-n5c6ccccc6c6ccccc65)cc4)nc3)nc(-c3ccccn3)n2)cc1]

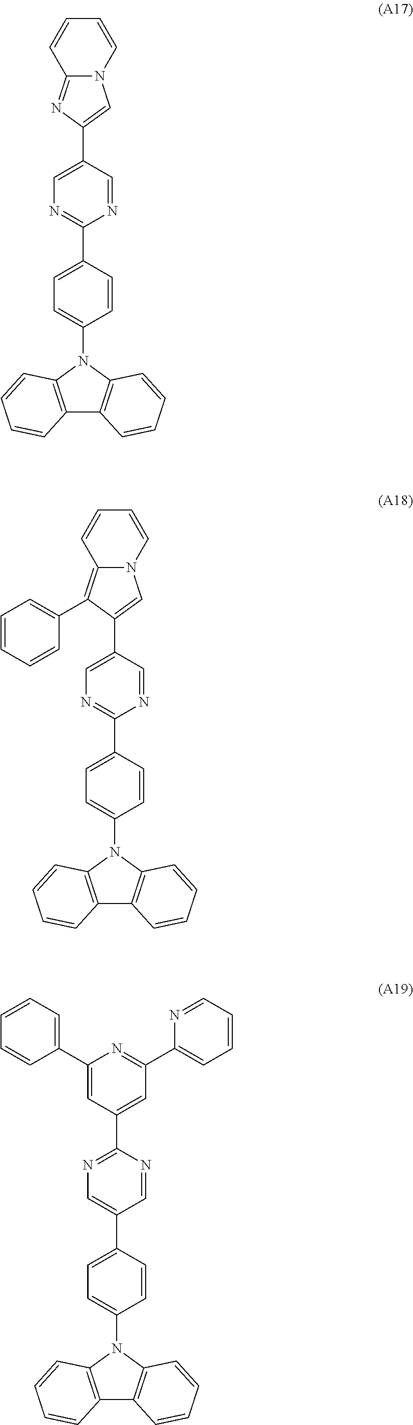 [SMILES: c1ccc2c(c1)c1ccccc1n2-c1ccc(-c2ncc(-c3cn4ccccc4n3)cn2)cc1 ; c1ccc(-c2c(-c3cnc(-c4ccc(-n5c6ccccc6c6ccccc65)cc4)nc3)cn3ccccc23)cc1 ; c1ccc(-c2cc(-c3ncc(-c4ccc(-n5c6ccccc6c6ccccc65)cc4)cn3)cc(-c3ccccn3)n2)cc1]

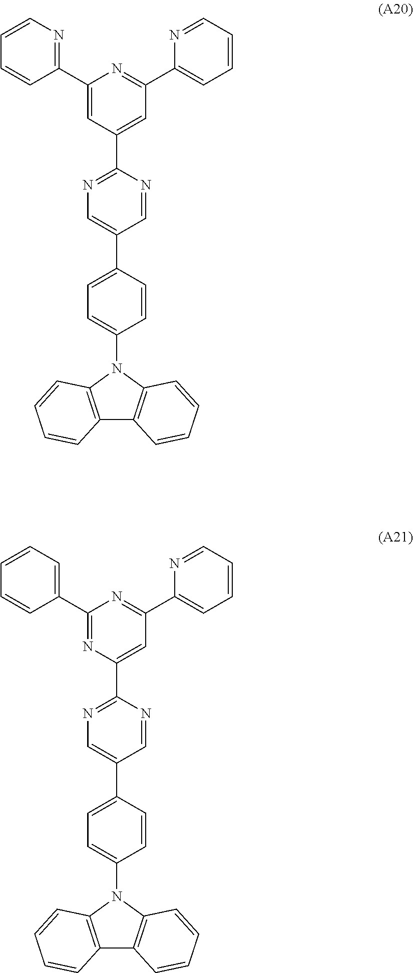 [SMILES: c1ccc(-c2cc(-c3ncc(-c4ccc(-n5c6ccccc6c6ccccc65)cc4)cn3)cc(-c3ccccn3)n2)nc1 ; c1ccc(-c2nc(-c3ccccn3)cc(-c3ncc(-c4ccc(-n5c6ccccc6c6ccccc65)cc4)cn3)n2)cc1]

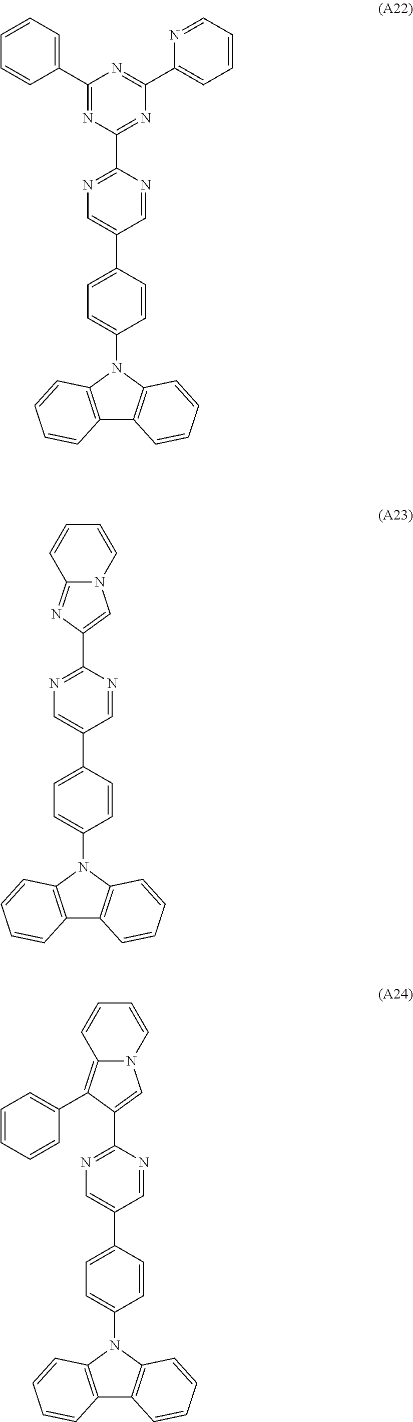 [SMILES: c1ccc(-c2nc(-c3ccccn3)nc(-c3ncc(-c4ccc(-n5c6ccccc6c6ccccc65)cc4)cn3)n2)cc1 ; c1ccc2c(c1)c1ccccc1n2-c1ccc(-c2cnc(-c3cn4ccccc4n3)nc2)cc1 ; c1ccc(-c2c(-c3ncc(-c4ccc(-n5c6ccccc6c6ccccc65)cc4)cn3)cn3ccccc23)cc1]

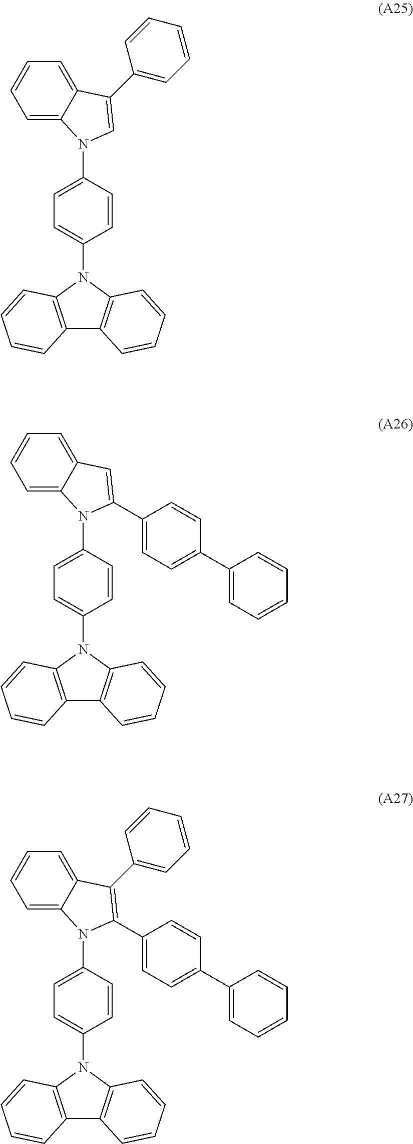 [SMILES: c1ccc(-c2cn(-c3ccc(-n4c5ccccc5c5ccccc54)cc3)c3ccccc23)cc1 ; c1ccc(-c2ccc(-c3cc4ccccc4n3-c3ccc(-n4c5ccccc5c5ccccc54)cc3)cc2)cc1 ; c1ccc(-c2ccc(-c3c(-c4ccccc4)c4ccccc4n3-c3ccc(-n4c5ccccc5c5ccccc54)cc3)cc2)cc1]

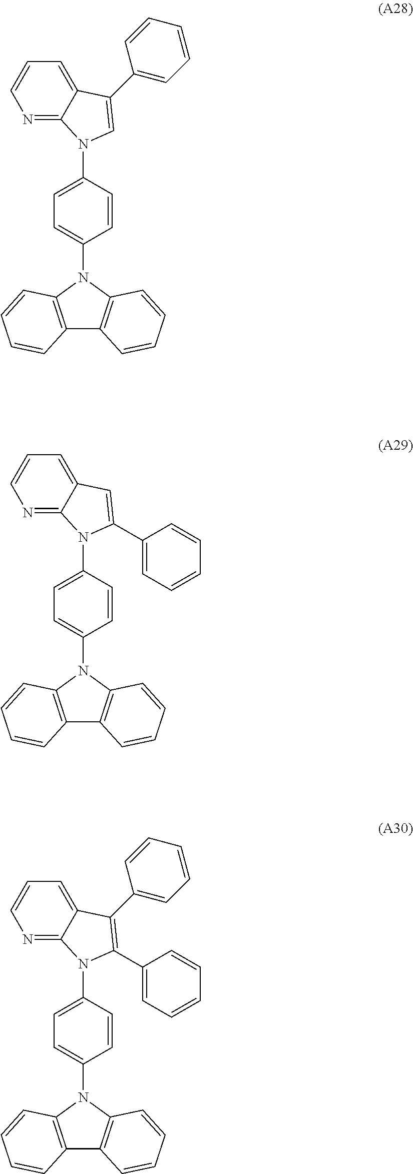 [SMILES: c1ccc(-c2cn(-c3ccc(-n4c5ccccc5c5ccccc54)cc3)c3ncccc23)cc1 ; c1ccc(-c2cc3cccnc3n2-c2ccc(-n3c4ccccc4c4ccccc43)cc2)cc1 ; c1ccc(-c2c(-c3ccccc3)n(-c3ccc(-n4c5ccccc5c5ccccc54)cc3)c3ncccc23)cc1]

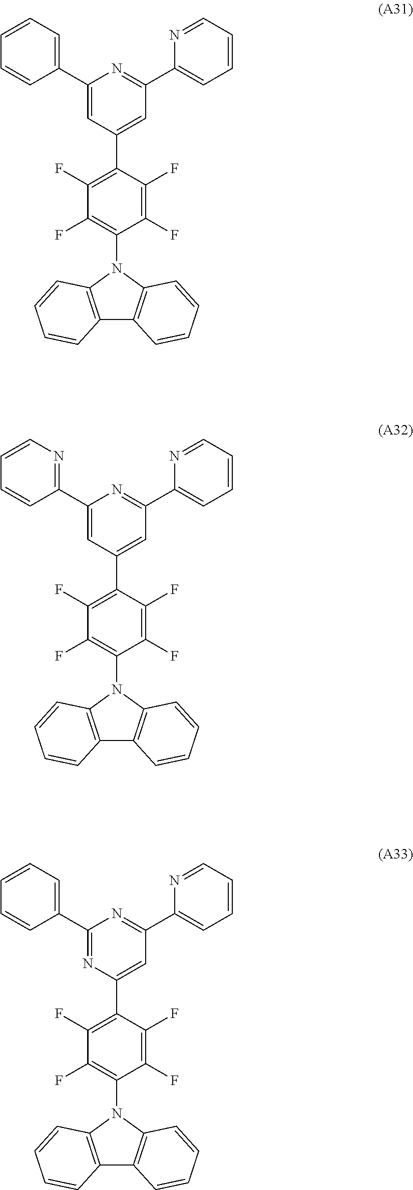 [SMILES: Fc1c(F)c(-n2c3ccccc3c3ccccc32)c(F)c(F)c1-c1cc(-c2ccccc2)nc(-c2ccccn2)c1 ; Fc1c(F)c(-n2c3ccccc3c3ccccc32)c(F)c(F)c1-c1cc(-c2ccccn2)nc(-c2ccccn2)c1 ; Fc1c(F)c(-n2c3ccccc3c3ccccc32)c(F)c(F)c1-c1cc(-c2ccccn2)nc(-c2ccccc2)n1]

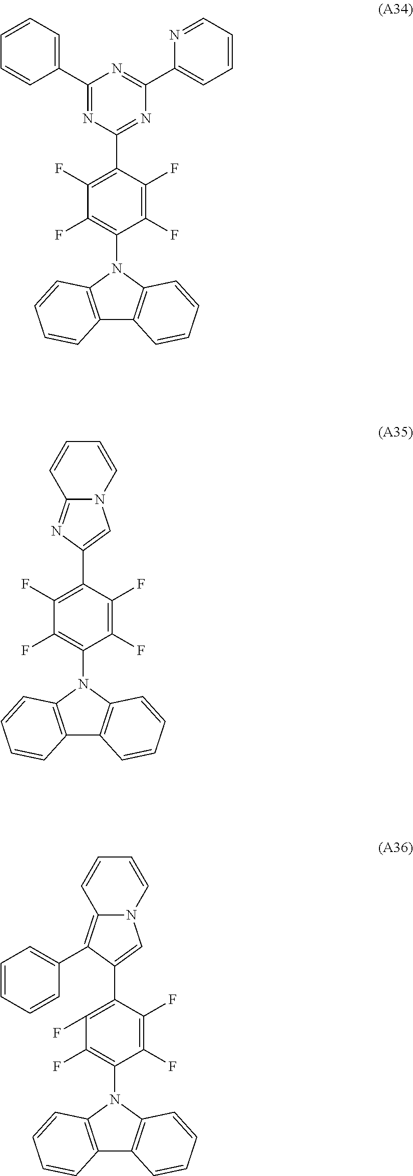 [SMILES: Fc1c(F)c(-n2c3ccccc3c3ccccc32)c(F)c(F)c1-c1nc(-c2ccccc2)nc(-c2ccccn2)n1 ; Fc1c(F)c(-n2c3ccccc3c3ccccc32)c(F)c(F)c1-c1cn2ccccc2n1 ; Fc1c(F)c(-n2c3ccccc3c3ccccc32)c(F)c(F)c1-c1cn2ccccc2c1-c1ccccc1]

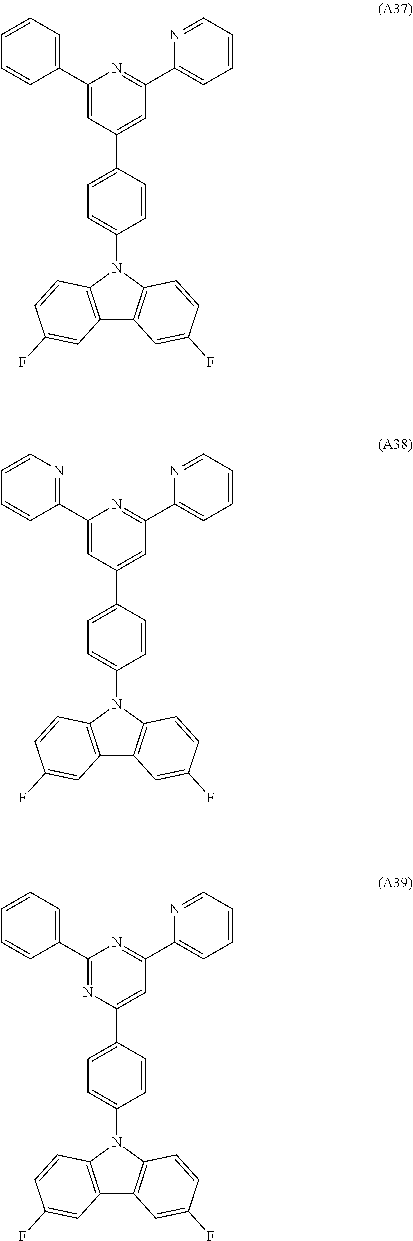 [SMILES: Fc1ccc2c(c1)c1cc(F)ccc1n2-c1ccc(-c2cc(-c3ccccc3)nc(-c3ccccn3)c2)cc1 ; Fc1ccc2c(c1)c1cc(F)ccc1n2-c1ccc(-c2cc(-c3ccccn3)nc(-c3ccccn3)c2)cc1 ; Fc1ccc2c(c1)c1cc(F)ccc1n2-c1ccc(-c2cc(-c3ccccn3)nc(-c3ccccc3)n2)cc1]

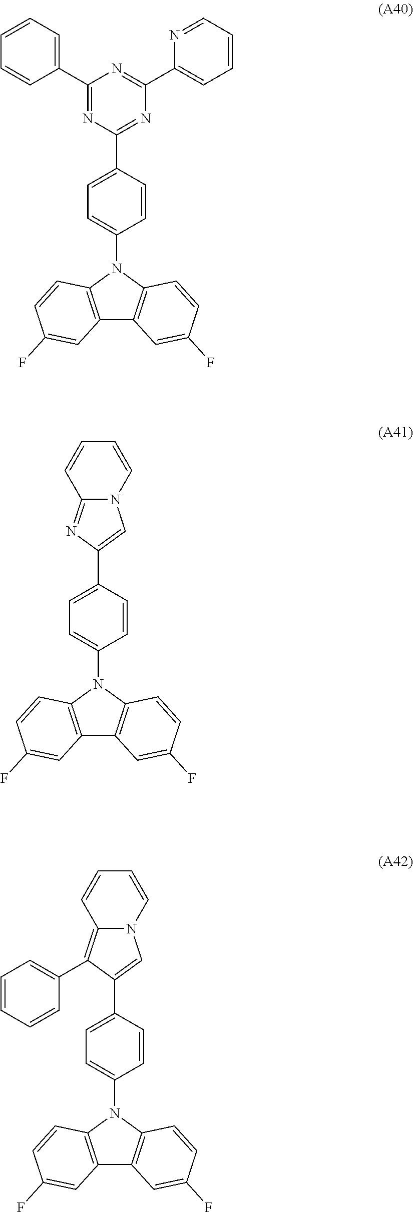 [SMILES: Fc1ccc2c(c1)c1cc(F)ccc1n2-c1ccc(-c2nc(-c3ccccc3)nc(-c3ccccn3)n2)cc1 ; Fc1ccc2c(c1)c1cc(F)ccc1n2-c1ccc(-c2cn3ccccc3n2)cc1 ; Fc1ccc2c(c1)c1cc(F)ccc1n2-c1ccc(-c2cn3ccccc3c2-c2ccccc2)cc1]

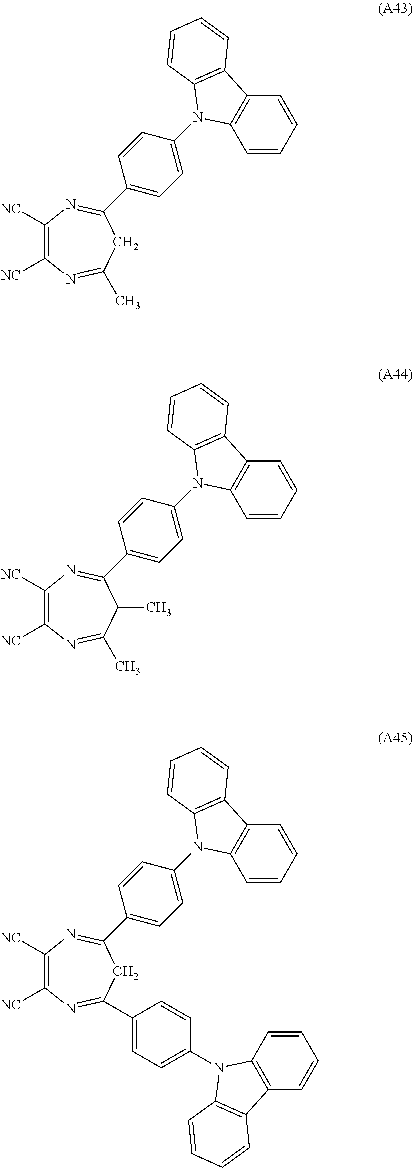 [SMILES: CC1=NC(C#N)=C(C#N)N=C(c2ccc(-n3c4ccccc4c4ccccc43)cc2)C1 ; CC1=NC(C#N)=C(C#N)N=C(c2ccc(-n3c4ccccc4c4ccccc43)cc2)C1C ; N#CC1=C(C#N)N=C(c2ccc(-n3c4ccccc4c4ccccc43)cc2)CC(c2ccc(-n3c4ccccc4c4ccccc43)cc2)=N1]

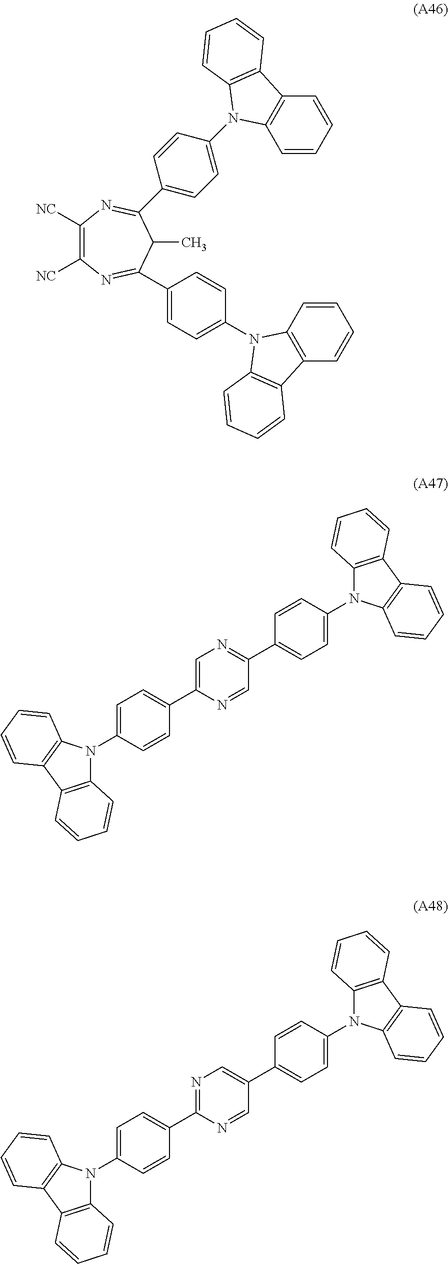 [SMILES: CC1C(c2ccc(-n3c4ccccc4c4ccccc43)cc2)=NC(C#N)=C(C#N)N=C1c1ccc(-n2c3ccccc3c3ccccc32)cc1 ; c1ccc2c(c1)c1ccccc1n2-c1ccc(-c2cnc(-c3ccc(-n4c5ccccc5c5ccccc54)cc3)cn2)cc1 ; c1ccc2c(c1)c1ccccc1n2-c1ccc(-c2cnc(-c3ccc(-n4c5ccccc5c5ccccc54)cc3)nc2)cc1]

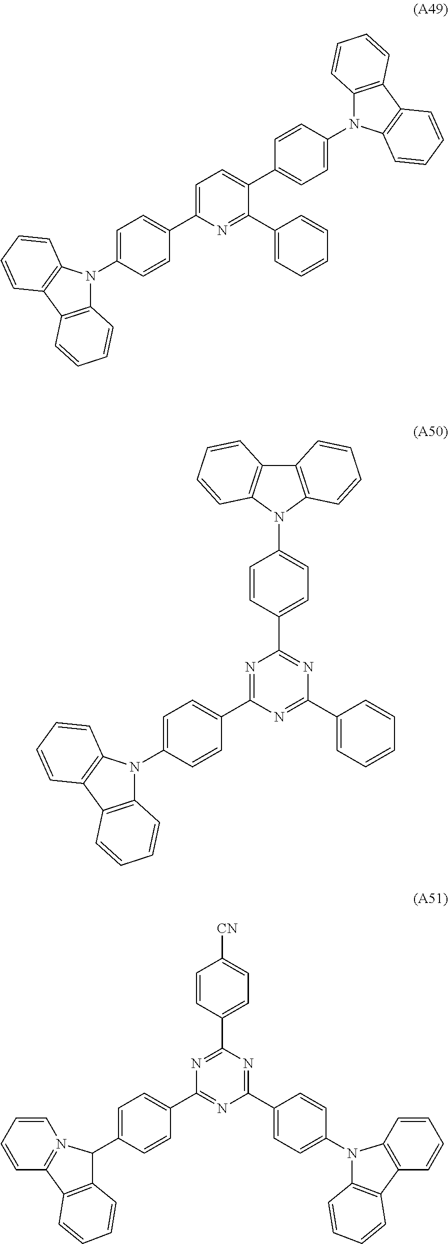

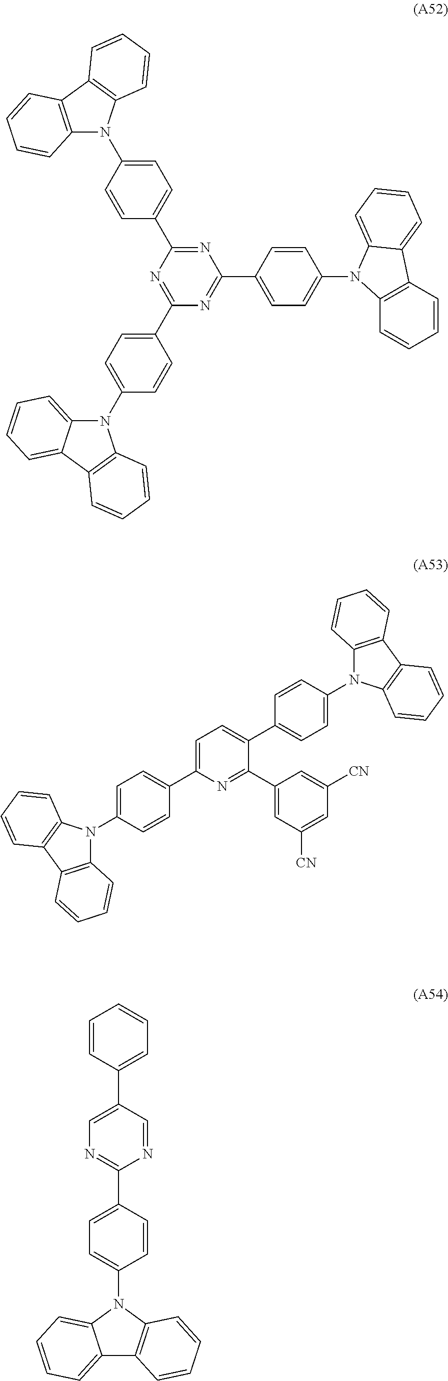 [SMILES: c1ccc2c(c1)c1ccccc1n2-c1ccc(-c2nc(-c3ccc(-n4c5ccccc5c5ccccc54)cc3)nc(-c3ccc(-n4c5ccccc5c5ccccc54)cc3)n2)cc1 ; N#Cc1cc(C#N)cc(-c2nc(-c3ccc(-n4c5ccccc5c5ccccc54)cc3)ccc2-c2ccc(-n3c4ccccc4c4ccccc43)cc2)c1 ; c1ccc(-c2cnc(-c3ccc(-n4c5ccccc5c5ccccc54)cc3)nc2)cc1]

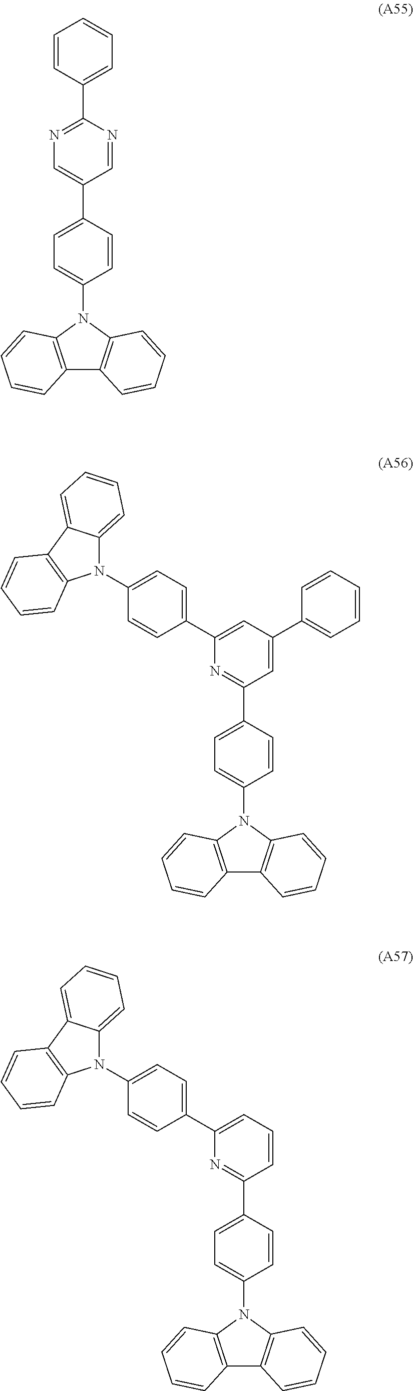 [SMILES: c1ccc(-c2ncc(-c3ccc(-n4c5ccccc5c5ccccc54)cc3)cn2)cc1 ; c1ccc(-c2cc(-c3ccc(-n4c5ccccc5c5ccccc54)cc3)nc(-c3ccc(-n4c5ccccc5c5ccccc54)cc3)c2)cc1 ; c1cc(-c2ccc(-n3c4ccccc4c4ccccc43)cc2)nc(-c2ccc(-n3c4ccccc4c4ccccc43)cc2)c1]

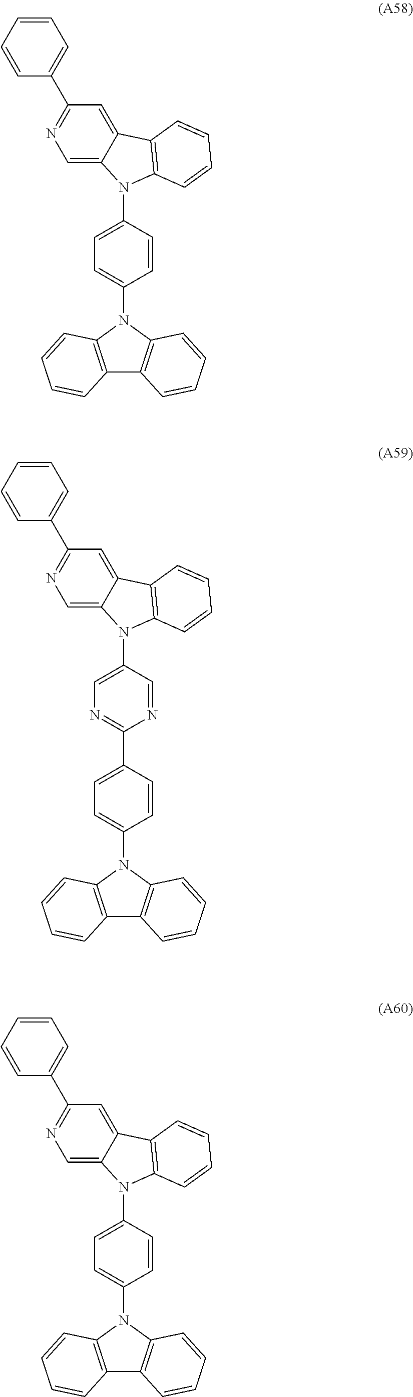 [SMILES: c1ccc(-c2cc3c4ccccc4n(-c4ccc(-n5c6ccccc6c6ccccc65)cc4)c3cn2)cc1 ; c1ccc(-c2cc3c4ccccc4n(-c4cnc(-c5ccc(-n6c7ccccc7c7ccccc76)cc5)nc4)c3cn2)cc1 ; c1ccc(-c2cc3c4ccccc4n(-c4ccc(-n5c6ccccc6c6ccccc65)cc4)c3cn2)cc1]

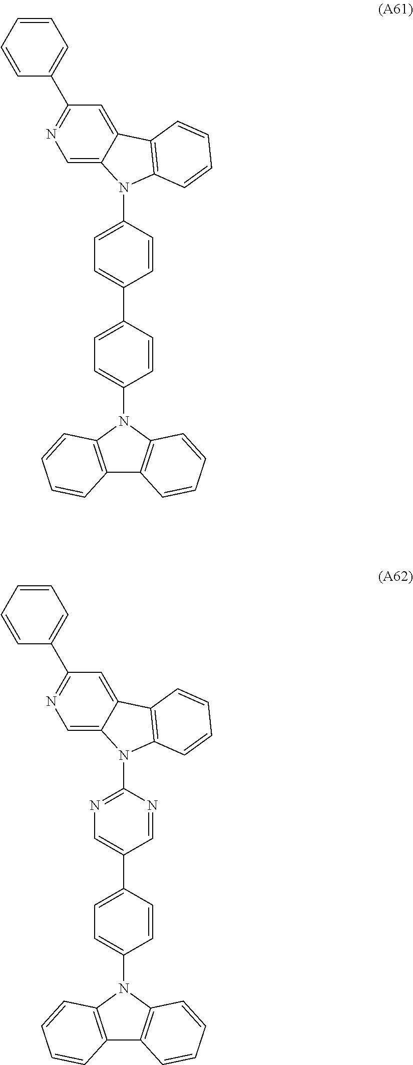 [SMILES: c1ccc(-c2cc3c4ccccc4n(-c4ccc(-c5ccc(-n6c7ccccc7c7ccccc76)cc5)cc4)c3cn2)cc1 ; c1ccc(-c2cc3c4ccccc4n(-c4ncc(-c5ccc(-n6c7ccccc7c7ccccc76)cc5)cn4)c3cn2)cc1]

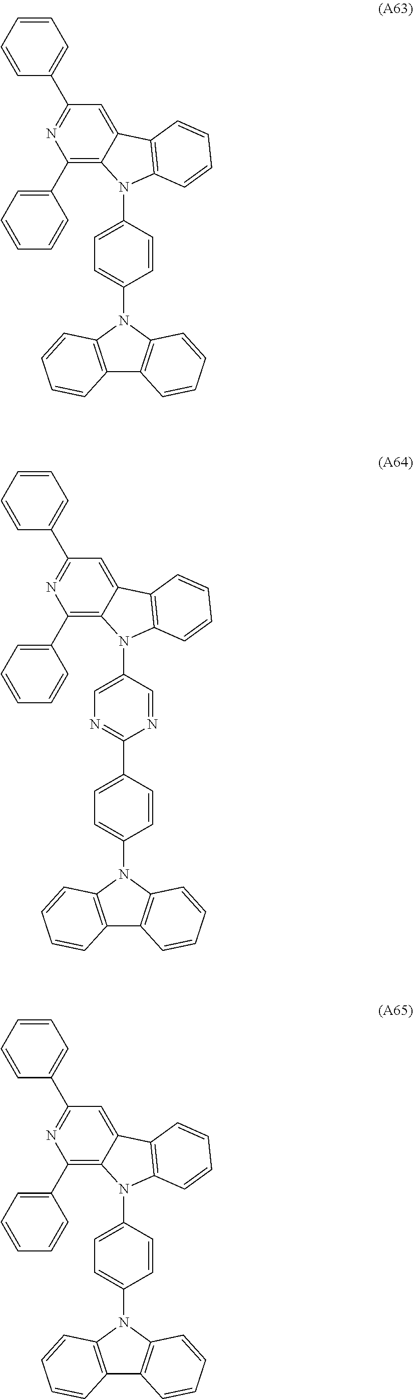 [SMILES: c1ccc(-c2cc3c4ccccc4n(-c4ccc(-n5c6ccccc6c6ccccc65)cc4)c3c(-c3ccccc3)n2)cc1 ; c1ccc(-c2cc3c4ccccc4n(-c4cnc(-c5ccc(-n6c7ccccc7c7ccccc76)cc5)nc4)c3c(-c3ccccc3)n2)cc1 ; c1ccc(-c2cc3c4ccccc4n(-c4ccc(-n5c6ccccc6c6ccccc65)cc4)c3c(-c3ccccc3)n2)cc1]

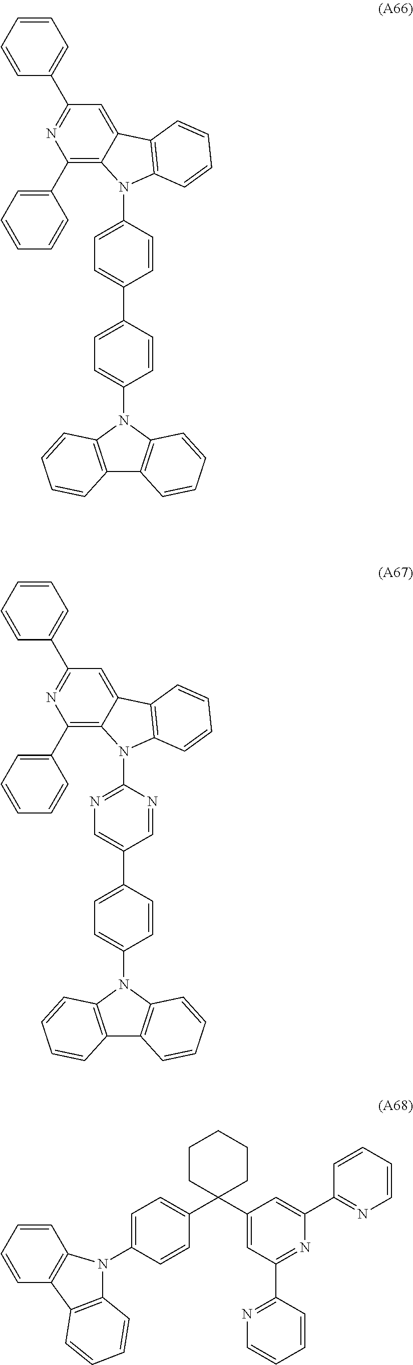 [SMILES: c1ccc(-c2cc3c4ccccc4n(-c4ccc(-c5ccc(-n6c7ccccc7c7ccccc76)cc5)cc4)c3c(-c3ccccc3)n2)cc1 ; c1ccc(-c2cc3c4ccccc4n(-c4ncc(-c5ccc(-n6c7ccccc7c7ccccc76)cc5)cn4)c3c(-c3ccccc3)n2)cc1 ; c1ccc(-c2cc(C3(c4ccc(-n5c6ccccc6c6ccccc65)cc4)CCCCC3)cc(-c3ccccn3)n2)nc1]

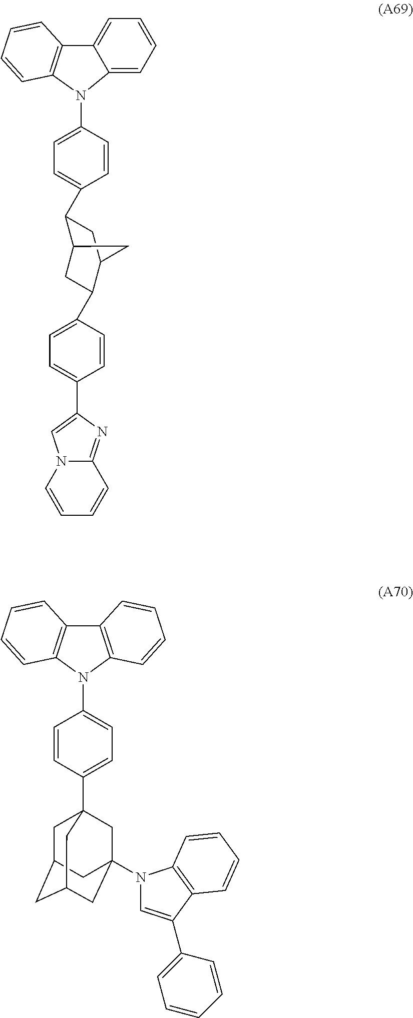 [SMILES: c1ccc2c(c1)c1ccccc1n2-c1ccc(C2CC3CC2CC3c2ccc(-c3cn4ccccc4n3)cc2)cc1 ; c1ccc(-c2cn(C34CC5CC(CC(c6ccc(-n7c8ccccc8c8ccccc87)cc6)(C5)C3)C4)c3ccccc23)cc1]

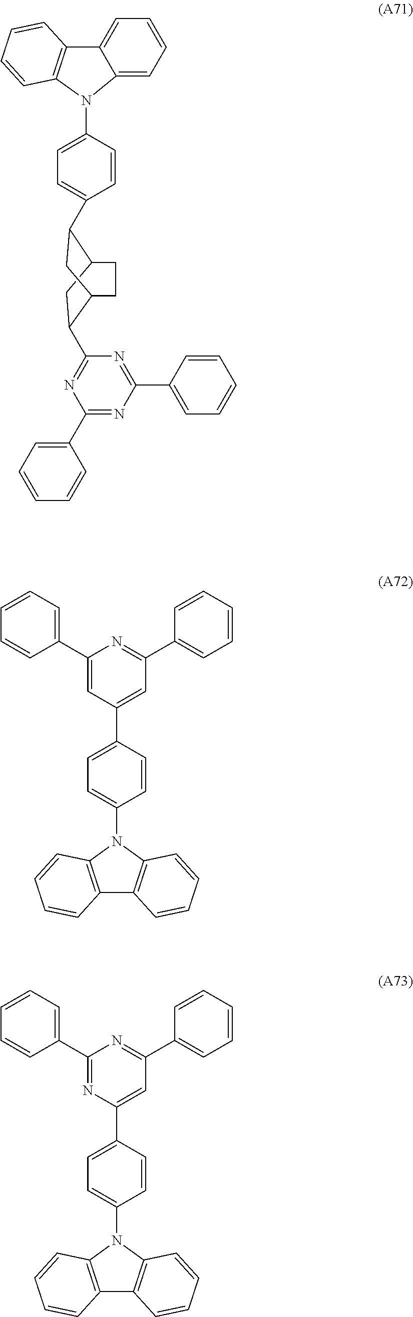 [SMILES: c1ccc(-c2nc(-c3ccccc3)nc(C3CC4CCC3CC4c3ccc(-n4c5ccccc5c5ccccc54)cc3)n2)cc1 ; c1ccc(-c2cc(-c3ccc(-n4c5ccccc5c5ccccc54)cc3)cc(-c3ccccc3)n2)cc1 ; c1ccc(-c2cc(-c3ccc(-n4c5ccccc5c5ccccc54)cc3)nc(-c3ccccc3)n2)cc1]

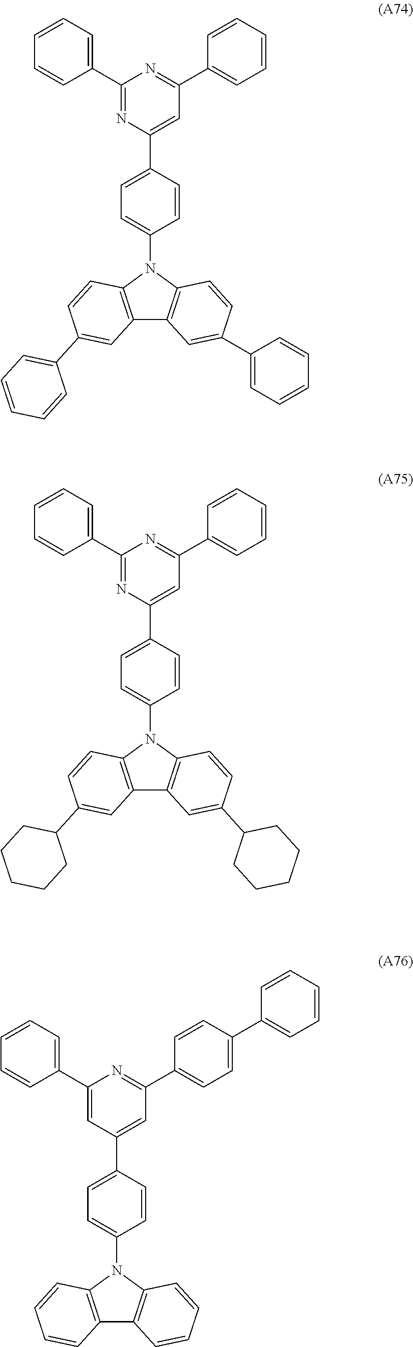 [SMILES: c1ccc(-c2ccc3c(c2)c2cc(-c4ccccc4)ccc2n3-c2ccc(-c3cc(-c4ccccc4)nc(-c4ccccc4)n3)cc2)cc1 ; c1ccc(-c2cc(-c3ccc(-n4c5ccc(C6CCCCC6)cc5c5cc(C6CCCCC6)ccc54)cc3)nc(-c3ccccc3)n2)cc1 ; c1ccc(-c2ccc(-c3cc(-c4ccc(-n5c6ccccc6c6ccccc65)cc4)cc(-c4ccccc4)n3)cc2)cc1]

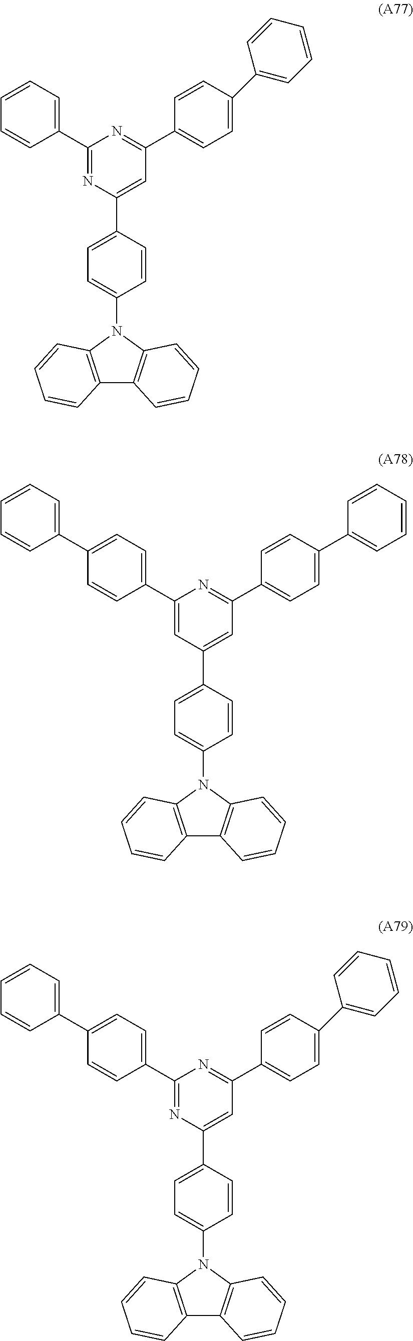 [SMILES: c1ccc(-c2ccc(-c3cc(-c4ccc(-n5c6ccccc6c6ccccc65)cc4)nc(-c4ccccc4)n3)cc2)cc1 ; c1ccc(-c2ccc(-c3cc(-c4ccc(-n5c6ccccc6c6ccccc65)cc4)cc(-c4ccc(-c5ccccc5)cc4)n3)cc2)cc1 ; c1ccc(-c2ccc(-c3cc(-c4ccc(-n5c6ccccc6c6ccccc65)cc4)nc(-c4ccc(-c5ccccc5)cc4)n3)cc2)cc1]

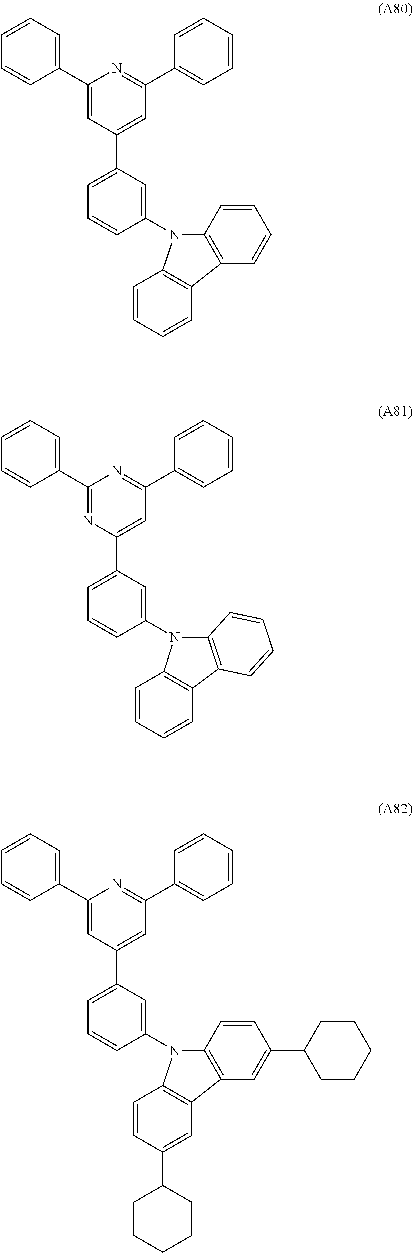 [SMILES: c1ccc(-c2cc(-c3cccc(-n4c5ccccc5c5ccccc54)c3)cc(-c3ccccc3)n2)cc1 ; c1ccc(-c2cc(-c3cccc(-n4c5ccccc5c5ccccc54)c3)nc(-c3ccccc3)n2)cc1 ; c1ccc(-c2cc(-c3cccc(-n4c5ccc(C6CCCCC6)cc5c5cc(C6CCCCC6)ccc54)c3)cc(-c3ccccc3)n2)cc1]

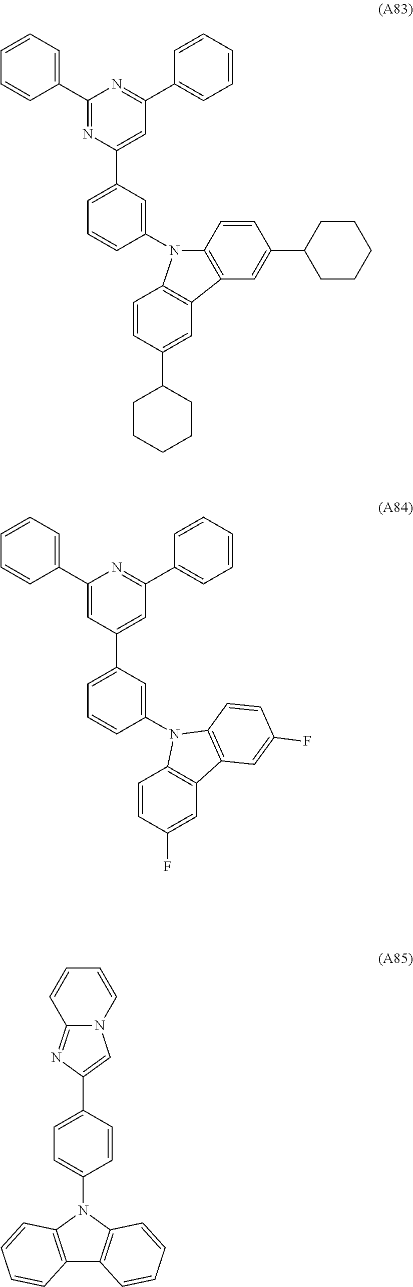 [SMILES: c1ccc(-c2cc(-c3cccc(-n4c5ccc(C6CCCCC6)cc5c5cc(C6CCCCC6)ccc54)c3)nc(-c3ccccc3)n2)cc1 ; Fc1ccc2c(c1)c1cc(F)ccc1n2-c1cccc(-c2cc(-c3ccccc3)nc(-c3ccccc3)c2)c1 ; c1ccc2c(c1)c1ccccc1n2-c1ccc(-c2cn3ccccc3n2)cc1]

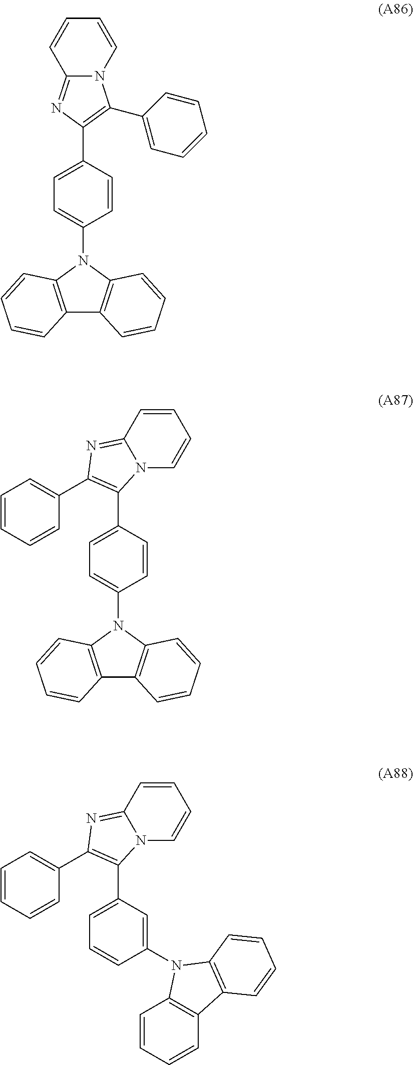 [SMILES: c1ccc(-c2c(-c3ccc(-n4c5ccccc5c5ccccc54)cc3)nc3ccccn23)cc1 ; c1ccc(-c2nc3ccccn3c2-c2ccc(-n3c4ccccc4c4ccccc43)cc2)cc1 ; c1ccc(-c2nc3ccccn3c2-c2cccc(-n3c4ccccc4c4ccccc43)c2)cc1]

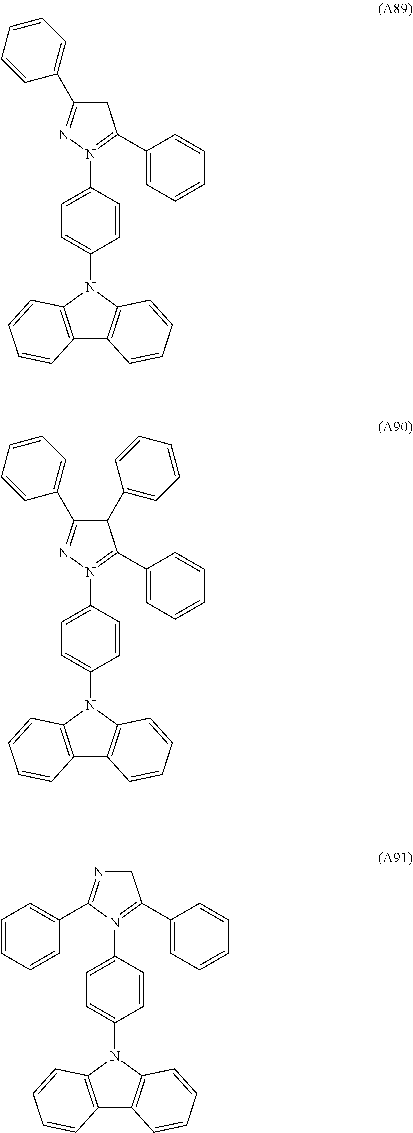

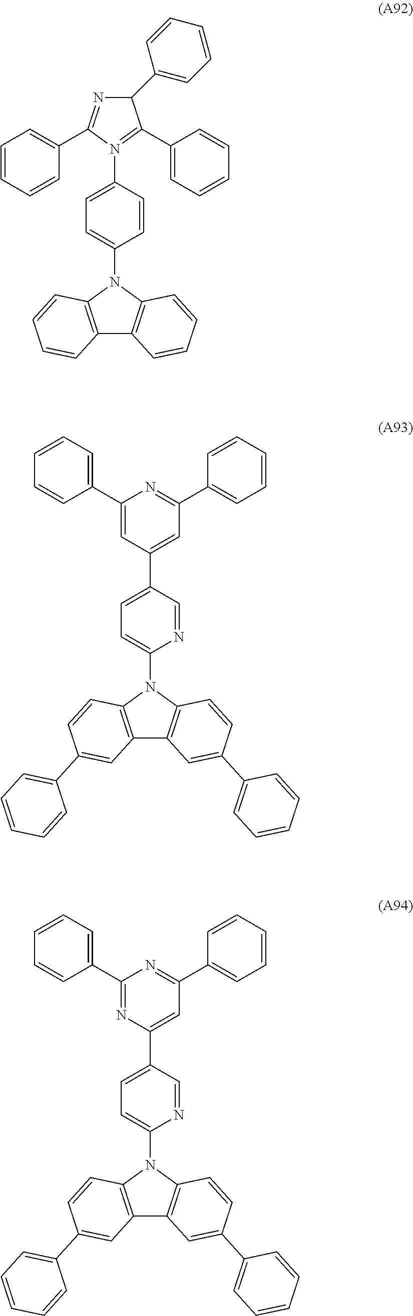

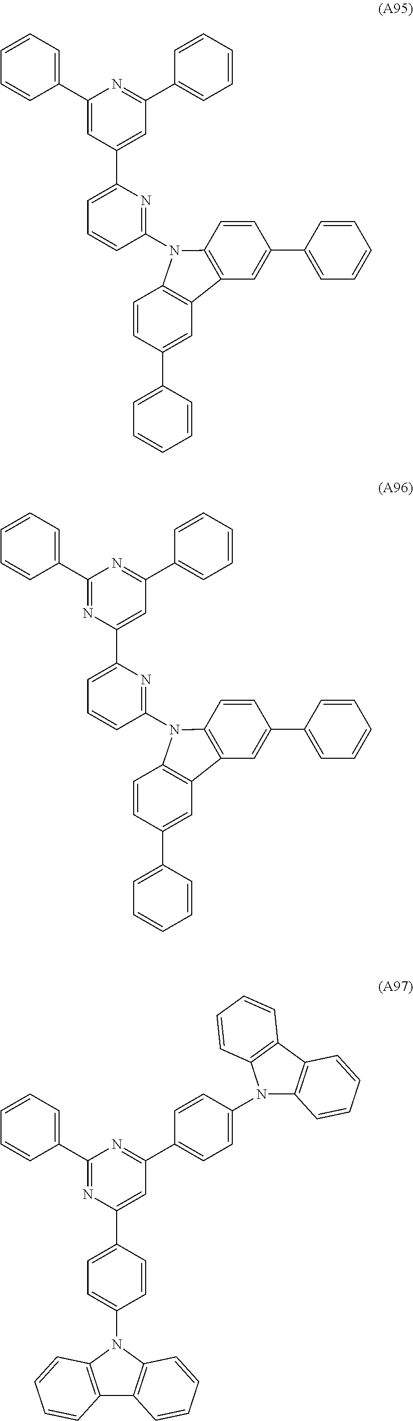 [SMILES: c1ccc(-c2ccc3c(c2)c2cc(-c4ccccc4)ccc2n3-c2cccc(-c3cc(-c4ccccc4)nc(-c4ccccc4)c3)n2)cc1 ; c1ccc(-c2ccc3c(c2)c2cc(-c4ccccc4)ccc2n3-c2cccc(-c3cc(-c4ccccc4)nc(-c4ccccc4)n3)n2)cc1 ; c1ccc(-c2nc(-c3ccc(-n4c5ccccc5c5ccccc54)cc3)cc(-c3ccc(-n4c5ccccc5c5ccccc54)cc3)n2)cc1]

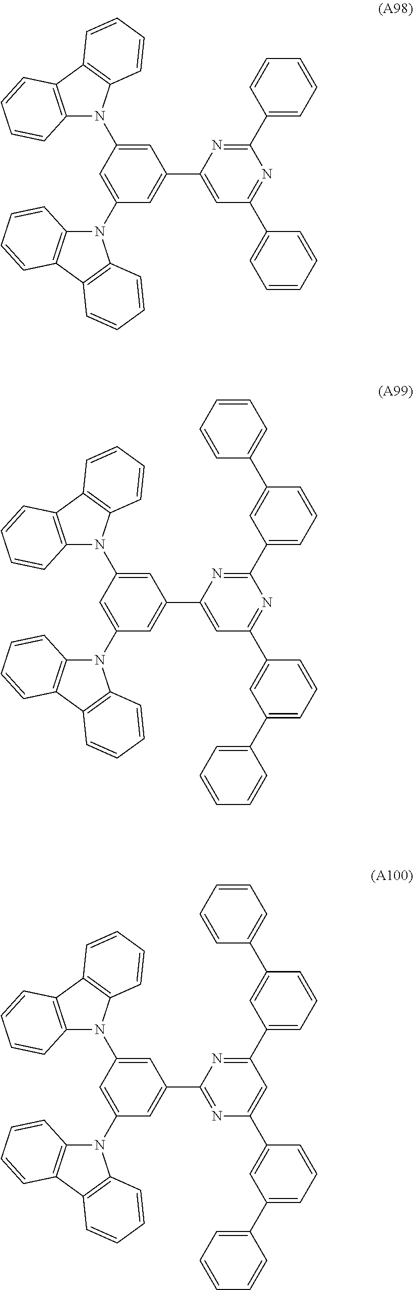 [SMILES: c1ccc(-c2cc(-c3cc(-n4c5ccccc5c5ccccc54)cc(-n4c5ccccc5c5ccccc54)c3)nc(-c3ccccc3)n2)cc1 ; c1ccc(-c2cccc(-c3cc(-c4cc(-n5c6ccccc6c6ccccc65)cc(-n5c6ccccc6c6ccccc65)c4)nc(-c4cccc(-c5ccccc5)c4)n3)c2)cc1 ; c1ccc(-c2cccc(-c3cc(-c4cccc(-c5ccccc5)c4)nc(-c4cc(-n5c6ccccc6c6ccccc65)cc(-n5c6ccccc6c6ccccc65)c4)n3)c2)cc1]

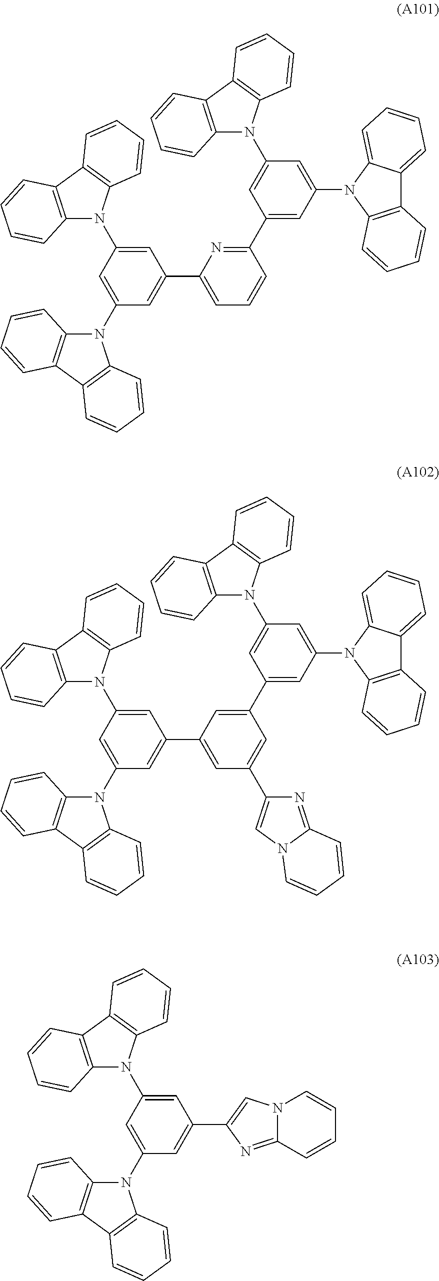 [SMILES: c1cc(-c2cc(-n3c4ccccc4c4ccccc43)cc(-n3c4ccccc4c4ccccc43)c2)nc(-c2cc(-n3c4ccccc4c4ccccc43)cc(-n3c4ccccc4c4ccccc43)c2)c1 ; c1ccc2c(c1)c1ccccc1n2-c1cc(-c2cc(-c3cc(-n4c5ccccc5c5ccccc54)cc(-n4c5ccccc5c5ccccc54)c3)cc(-c3cn4ccccc4n3)c2)cc(-n2c3ccccc3c3ccccc32)c1 ; c1ccc2c(c1)c1ccccc1n2-c1cc(-c2cn3ccccc3n2)cc(-n2c3ccccc3c3ccccc32)c1]

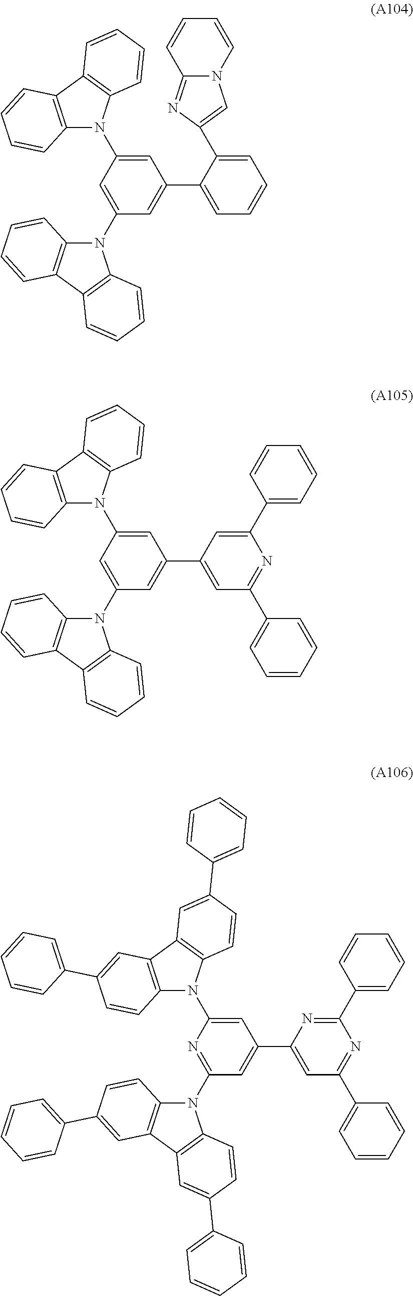 [SMILES: c1ccc(-c2cn3ccccc3n2)c(-c2cc(-n3c4ccccc4c4ccccc43)cc(-n3c4ccccc4c4ccccc43)c2)c1 ; c1ccc(-c2cc(-c3cc(-n4c5ccccc5c5ccccc54)cc(-n4c5ccccc5c5ccccc54)c3)cc(-c3ccccc3)n2)cc1 ; c1ccc(-c2ccc3c(c2)c2cc(-c4ccccc4)ccc2n3-c2cc(-c3cc(-c4ccccc4)nc(-c4ccccc4)n3)cc(-n3c4ccc(-c5ccccc5)cc4c4cc(-c5ccccc5)ccc43)n2)cc1]

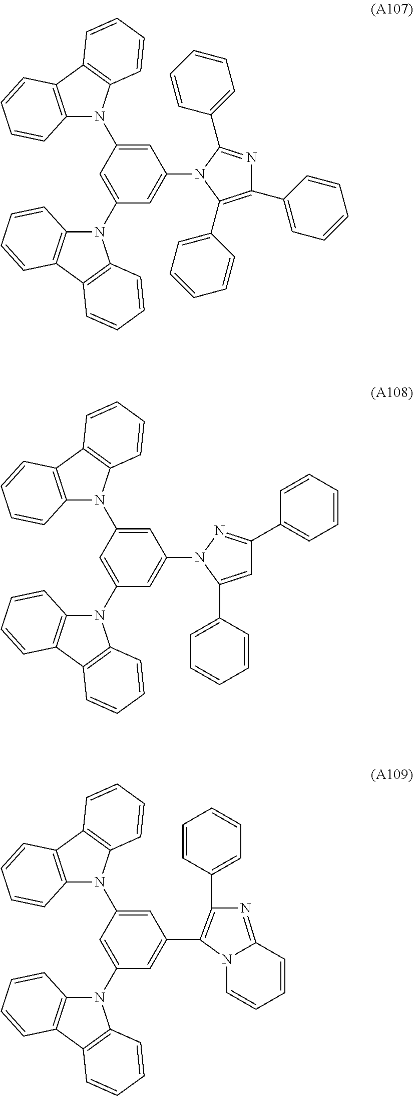 [SMILES: c1ccc(-c2nc(-c3ccccc3)n(-c3cc(-n4c5ccccc5c5ccccc54)cc(-n4c5ccccc5c5ccccc54)c3)c2-c2ccccc2)cc1 ; c1ccc(-c2cc(-c3ccccc3)n(-c3cc(-n4c5ccccc5c5ccccc54)cc(-n4c5ccccc5c5ccccc54)c3)n2)cc1 ; c1ccc(-c2nc3ccccn3c2-c2cc(-n3c4ccccc4c4ccccc43)cc(-n3c4ccccc4c4ccccc43)c2)cc1]

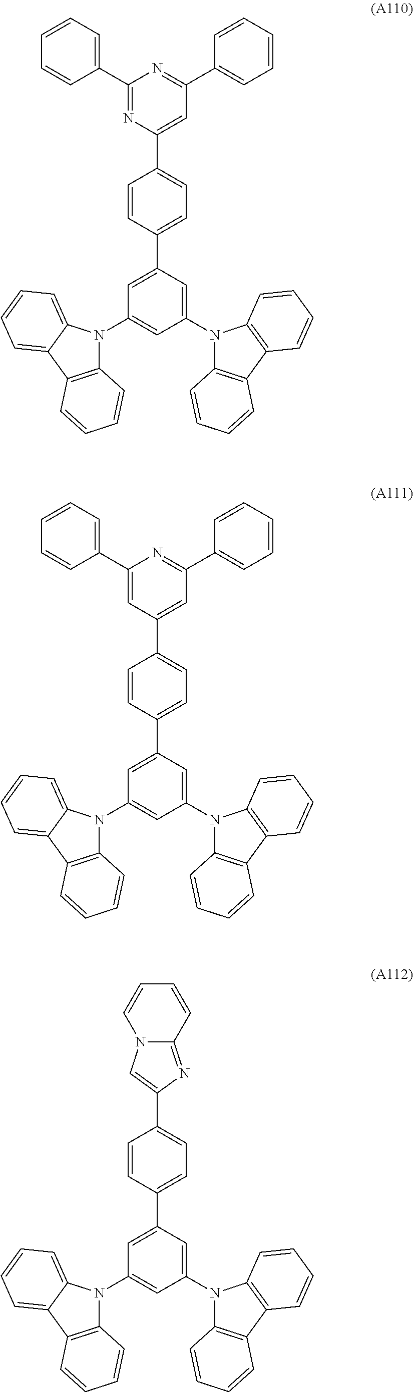 [SMILES: c1ccc(-c2cc(-c3ccc(-c4cc(-n5c6ccccc6c6ccccc65)cc(-n5c6ccccc6c6ccccc65)c4)cc3)nc(-c3ccccc3)n2)cc1 ; c1ccc(-c2cc(-c3ccc(-c4cc(-n5c6ccccc6c6ccccc65)cc(-n5c6ccccc6c6ccccc65)c4)cc3)cc(-c3ccccc3)n2)cc1 ; c1ccc2c(c1)c1ccccc1n2-c1cc(-c2ccc(-c3cn4ccccc4n3)cc2)cc(-n2c3ccccc3c3ccccc32)c1]

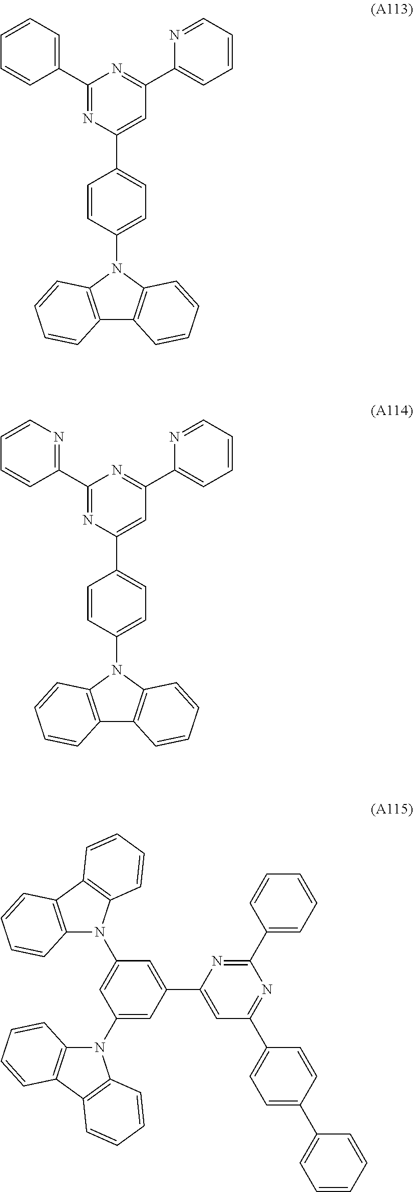 [SMILES: c1ccc(-c2nc(-c3ccc(-n4c5ccccc5c5ccccc54)cc3)cc(-c3ccccn3)n2)cc1 ; c1ccc(-c2cc(-c3ccc(-n4c5ccccc5c5ccccc54)cc3)nc(-c3ccccn3)n2)nc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

With regard to phosphorescent emitter materials capable of use in the OLEDs of the present invention, Ir(2-phenylquinoline) and Ir(1-phenylisoquinoline) type phosphorescent materials have been synthesized, and OLEDs incorporating them as the dopant emitters have been fabricated. Such devices may advantageously exhibit high current efficiency, high stability, narrow emission, high processibility (such as high solubility and low evaporation temperature), high luminous efficiency, and/or high luminous efficiency.

Using the base structure of Ir(3-Meppy)₃, different alkyl and fluoro substitution patterns have been studied to establish a structure-property relationship with respect to material processibility (evaporation temperature, evaporation stability, solubility, etc.) and device characteristics of Ir(2-phenylquinoline) and Ir(1-phenylisoquinoline) type phosphorescent materials. Alkyl and fluoro substitutions are particularly important because they offer a wide range of tenability in terms of evaporation temperature, solubility, energy levels, device efficiency, etc. Moreover, they are stable as functional groups chemically and in device operation when applied appropriately.

In one embodiment of the present invention, the phosphorescent emitter material comprises a phosphorescent organometallic complex having a substituted chemical structure represented by one of the following partial chemical structures represented by the following Formula:

LL′L″M

wherein M is a metal that forms octahedral complexes. L, L′, L″ are equivalent or inequivalent bidentate ligands wherein each L comprises a substituted or unsubstituted phenylpyridine ligand coordinated to M through an sp² hybridized carbon and N; and, one of L, L′ and L″ is inequivalent to at least one of the other two.

In an embodiment, the phosphorescent emitter material comprises a phosphorescent organometallic compound having a substituted chemical structure represented by the following chemical structure:

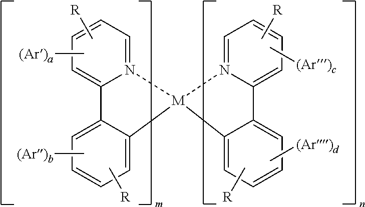

where each R is independently selected from the group consisting of H, alkyl, alkenyl, alkynyl, alkylaryl, CN, CF₃, CₙF₂ₙ₊₁, trifluorovinyl, CO₂R, C(O)R, NR₂, NO₂, OR, halo, aryl, heteroaryl, substituted aryl, substituted heteroaryl or a heterocyclic group;

Ar′, Ar″, Ar′″ and Ar″″ each independently represent a substituted or unsubstituted aryl or heteroaryl unfused substituent on the phenylpyridine ligand;

a is 0 or 1; b is 0 or 1; c is 0 or 1; d is 0 or 1; m is 1 or 2; n is 1 or 2;
m+n is the maximum number of ligands that can be coordinated to M, and
wherein at least one of a, b, c, and d is 1 and when at least one of a and b is 1 and at least one of b and c is 1, at least one of Ar′ and Ar″ is different from at least one of Ar′″ and Ar″″.

In another embodiment, the phosphorescent emitter material comprises a metal complex, and the metal complex comprises a metal atom selected from Ir, Pt, Os, Au, Cu, Re and Ru and a ligand. In yet another embodiment the metal complex has an ortho-metal bond. The metal atom is preferably Ir.

In a preferred embodiment, the phosphorescent emitter material comprises a phosphorescent organometallic complex having a substituted chemical structure represented by the following partial chemical structure (GD-1):

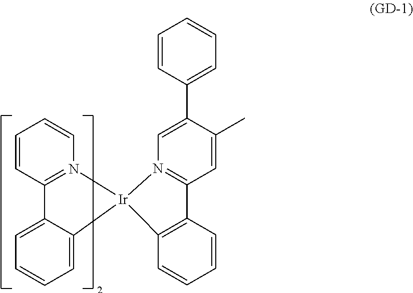

In a preferred embodiment, the present invention relates to an OLED wherein the host material comprises an unsubstituted aromatic hydrocarbon compound having the chemical structure represented by the formula (GH-1):

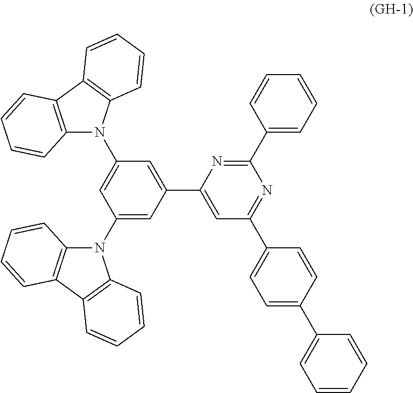 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

and wherein the phosphorescent emitter material comprises a phosphorescent organometallic compound having a substituted chemical structure represented by the following chemical structure:

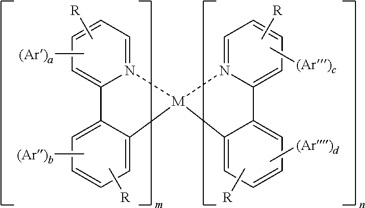

where each R is independently selected from the group consisting of H, alkyl, alkenyl, alkynyl, alkylaryl, CN, CF₃, CₙF₂ₙ₊₁, trifluorovinyl, CO₂R, C(O)R, NR₂, NO₂, OR, halo, aryl, heteroaryl, substituted aryl, substituted heteroaryl or a heterocylic group;

Ar′, Ar″, Ar′″ and Ar″″ each independently represent a substituted or unsubstituted aryl or heteroaryl unfused substituent on the phenylpyridine ligand;

a is 0 or 1; b is 0 or 1; c is 0 or 1; d is 0 or 1; m is 1 or 2; n is 1 or 2;
m+n is the maximum number of ligands that can be coordinated to M; and
wherein at least one of a, b, c, and d is 1 and when at least one of a and b is 1 and at least one of b and c is 1, at least one of Ar′ and Ar″ is different from at least one of Ar′″ and Ar″″.

The OLEDs of the present invention may comprise a hole transporting layer (hole injecting layer), and the above hole transporting layer (hole injecting layer) preferably contains the materials of the present invention. Also, the OLEDs of the present invention may comprise an electron transporting layer and/or a hole blocking layer, and the above electron transporting layer and/or hole blocking layer preferably contains the materials of the present invention.

The OLEDs of the present invention may contain a reductant dopant in an interlayer region between the cathode and the organic thin film layer. Such an OLED having the described structural constitution, may exhibit improved emission luminance and extended lifetime.

The reductant dopant includes at least one dopant selected from alkali metals, alkali metal complexes, alkali metal compounds, alkali earth metals, alkali earth metal complexes, alkali earth metal compounds, rare earth metals, rare earth metal complexes, rare earth metal compounds and the like.

Suitable alkali metals include Na (work function: 2.36 eV), K (work function: 2.28 eV), Rb (work function: 2.16 eV), Cs (work function: 1.95 eV) and the like, and the compounds having a work function of 2.9 eV or less are particularly preferred. Among them, K, Rb and Cs are preferred, more preferred are Rb or Cs, and even more preferred is Cs.

The alkali earth metals include Ca (work function: 2.9 eV), Sr (work function: 2.0 to 2.5 eV), Ba (work function: 2.52 eV) and the like, and the compounds having a work function of 2.9 eV or less are particularly preferred.

The rare earth metals include Sc, Y, Ce, Tb, Yb and the like, and the compounds having a work function of 2.9 eV or less are particularly preferred.

Among the metals described above, it is preferred to select metals having a high reducing ability, and addition of a relatively small amount thereof to the electron injecting region may make it possible to enhance the emission luminance and extend the lifetime of the OLED.

The alkali metal compounds include alkali metal oxides such as Li₂O, Cs₂O, K₂O and the like and alkali metal halides such as LiF, NaF, CsF, KF and the like. Preferred compounds include LiF, Li₂O and NaF.

The alkali earth metal compounds include BaO, SrO, CaO and BaₓSr₁₋ₓO (0<x<1), BaₓCa₁₋ₓO (0<x<1) and the like which are obtained by mixing the above compounds, and BaO, SrO and CaO are preferred.

The rare earth metals compound include YbF₃, ScF₃, ScO₃, Y₂O₃, Ce₂O₃, GdF₃, TbF₃ and the like, and YbF₃, ScF₃ and TbF₃ are preferred.

The alkali metal complex, the alkali earth metal complex and the rare earth metal complex shall not specifically be restricted as long as they contain at least one metal ion of alkali metal ions, alkali earth metal ions and rare earth metal ions. The ligand is preferably quinolinol, benzoquinolinol, acridinol, phenanthridinol, hydroxyphenyloxazole, hydroxyphenylthiazole, hydroxydiaryloxadiazole, hydroxydiarylthiadiazole, hydroxyphenylpyridine, hydroxyphenylbenzimidazole, hydroxybenzotriazole, hydroxyfulvorane, bipyridyl, phenanthroline, phthalocyanine, porphyrin, cyclopentadiene, β-diketones, azomethines and derivatives thereof. However, suitable materials are not restricted to the above-mentioned compounds.

The reductant dopant may be formed in an interfacial region, and is preferably in a layer form or an island form. The forming method may be a method in which a light emitting material forming an interfacial region and an organic substance corresponding to an electron injecting material are deposited at the same time while depositing the reductant dopant by a resistance heating vapor deposition method to thereby disperse the reductant dopant in the organic substance. The dispersion concentration has a ratio of organic substance to reductant dopant of from about 100:1 to 1:100, and preferably from about 5:1 to 1:5 in terms of the mole ratio.

When the reductant dopant is formed in a layer form, the light emitting material which is an organic layer in an interfacial region and the electron injecting material are formed in a layer form, and then the reductant dopant may be deposited alone by the resistance heating vapor deposition method to form the layer, preferably in a thickness of 0.1 to 15 nm.

When the reductant dopant is formed in an island form, the light emitting material which is an organic layer in an interfacial region and the electron injecting material are formed in an island form, and then the reductant dopant may be deposited alone by the resistance heating vapor deposition light emitting method to form the island preferably in a thickness of 0.05 to 1 nm.

A mole ratio of the main component to the reductant dopant in the OLEDs of the present invention is preferably main component:reductant dopant=5:1 to 1:5, more preferably 2:1 to 1:2 in terms of a mole ratio.

The OLEDs of the present invention preferably have an electron injecting layer between the light emitting layer and the cathode. In this regard, the electron injecting layer may be a layer which functions as an electron transporting layer. The electron injecting layer or the electron transporting layer is a layer for assisting injection of an electron into the light emitting layer, and it has a large electron mobility. The electron injecting layer is provided to control an energy level including relaxation of a sudden change in the energy level.

The forming methods of the respective layers in the OLEDs of the present invention shall not specifically be restricted, and forming methods carried out by a vacuum vapor deposition method, a spin coating method and the like which have so far publicly been known can be used. The organic thin film layer containing the host material compounds represented by the formula (GH-1) described above which is used for the OLEDs of the present invention can be formed by known methods such as by vacuum vapor deposition, molecular beam evaporation (MBE method), and coating methods such as dipping, spin coating, casting, bar coating and roll coating, each using a solution prepared by dissolving the compound in a solvent.

The film thicknesses of the respective organic layers in the OLEDs of the present invention shall not specifically be restricted. In general, too small film thicknesses may be associated with defects such as pinholes and the like, while too large film thicknesses require application of high voltage, and may lower the OLED's efficiency. Accordingly, film thicknesses are typically in the range of one to several nm to 1 μm.

By the combination of the present invention, the triplet energy level of the phosphorescent dopant and the triplet energy level of the host are properly regulated. As a result thereof, an organic electroluminescent (EL) device with a high efficiency and an extended lifetime is obtained.

The material for organic electroluminescence devices of the present invention comprises a host material compound represented by the following general formula (1) or (2):

(Cz-)ₙA (1)

Cz(-A)ₘ (2)

In the above formulae, Cz represents a substituted or unsubstituted arylcarbazolyl group or carbazolylalkylene group and n and m each represent an integer of 1 to 3.

It is preferable that the aryl group in the arylcarbazolyl group has 6 to 30 carbon atoms. Examples of the aryl group include a phenyl group, naphthyl group, anthryl group, phenanthryl group, naphthacenyl group, pyrenyl group, fluorenyl group, biphenyl group and terphenyl group. Among these groups, phenyl group, naphthyl group, biphenyl group and terphenyl group are preferable.

It is preferable that the alkylene group in the carbazolylalkylene group has 1 to 10 carbon atoms. Examples of the alkylene group include a methylene group, ethylene group, propylene group, isopropylene group, n-butylene group, s-butylene group, isobutylene group, t-butylene group, n-pentylene group, n-hexylene group, n-heptylene group, n-octylene group, hydroxymethylene group, chloromethylene group and aminomethylene group. Among these groups, methylene group, ethylene group, propylene group, isopropylene group, n-butylene group, t-butylene group and n-pentylene group are preferable.

In the general formulae (1) and (2), A represents a group represented by the following the general formula (3):

(M)ₚ-(L)_{q}-(M′)ᵣ (3)

M and M′ each independently represent a heteroaromatic ring having 2 to 40 carbon atoms and nitrogen atom and forming a substituted or unsubstituted ring, and M and M′ may represent the same ring or different rings.

Examples of the heteroaromatic ring having nitrogen atom include rings of pyridine, pyrimidine, pyrazine, triazine, aziridine, azaindolizine, indolizine, imidazole, indole, isoindole, indazole, purine, pteridine, β-carboline, naphthyridine, quinoxaline, terpyridine, bipyridine, acridine, phenanthroline, phenazine and imidazopyridine (preferably imidazo[1,2-a]pyridine). Among these rings, rings of pyridine, terpyridine, pyrimidine, imidazopyridine (preferably imidazo[1,2-a]pyridine) and triazine are preferable.

L represents a single bond, a substituted or unsubstituted aryl group or arylene group having 6 to 30 carbon atoms, a substituted or unsubstituted cycloalkylene group having 5 to 30 carbon atoms or a substituted or unsubstituted heteroaromatic ring having 2 to 30 carbon atoms. p represents an integer of 0 to 2, q represents an integer of 1 or 2, r represents an integer of 0 to 2, and p+r represents an integer of 1 or greater.

Examples of the aryl group having 6 to 30 carbon atoms include a phenyl group, biphenyl group, terphenyl group, naphthyl group, anthranyl group, phenanthryl group, pyrenyl group, chrysenyl group, fluoranthenyl group and perfluoroaryl groups. Among these groups, a phenyl group, biphenyl groups, terphenyl group and perfluoroaryl groups are preferable.

Examples of the arylene group having 6 to 30 carbon atoms include a phenylene group, biphenylene group, terphenylene group, naphthylene group, anthranylene group, phenanthrylene group, pyrenylene group, chrysenylene group, fluoranthenylene group and perfluoroarylene groups. Among these groups, a phenylene group, biphenylene group, terphenylene group and perfluoroarylene groups are preferable.

Examples of the cycloalkylene group having 5 to 30 carbon atoms include a cyclopentylene group, cyclohexylene group and cycloheptylene group. Among these groups, a cyclohexylene group is preferable.

Examples of the heteroaromatic group having 2 to 30 carbon atoms include a 1-pyrrolyl group, 2-pyrrolyl group, 3-pyrrolyl group, pyradinyl group, 2-pyridinyl group, 3-pyridinyl group, 4-pyridinyl group, 1-indolyl group, 2-indolyl group, 3-indolyl group, 4-indolyl group, 5-indolyl group, 6-indolyl group, 7-indolyl group, 1-isoindolyl group, 2-isoindolyl group, 3-isoindolyl group, 4-isoindolyl group, 5-isoindolyl group, 6-isoindolyl group, 7-isoindolyl group, 2-furyl group, 3-furyl group, 2-benzofuranyl group, 3-benzofuranyl group, 4-benzofuranyl group, 5-benzofuranyl group, 6-benzofuranyl group, 7-benzofuranyl group, 1-isobenzofuranyl group, 3-isobenzofuranyl group, 4-isobenzofuranyl group, 5-isobenzofuranyl group, 6-isobenzofuranyl group, 7-isobenzofuranyl group, 2-quinolyl group, 3-quinolyl group, 4-quinolyl group, 5-quinolyl group, 6-quinolyl group, 7-quinolyl group, 8-quinolyl group, 1-isoquinolyl group, 3-isoquinolyl group, 4-isoquinolyl group, 5-isoquinolyl group, 6-isoquinolyl group, 7-isoquinolyl group, 8-isoquinolyl group, 2-quinoxanyl group, 5-quinoxanyl group, 6-quinoxanyl group, 1-carbazolyl group, 2-carbazolyl group, 3-carbazolyl group, 4-carbazolyl group, 9-carbazolyl group, 1-phenanthrydinyl group, 2-phenanthrydinyl group, 3-phenanthrydinyl group, 4-phenanthrydinyl group, 6-phenanthrydinyl group, 7-phenanthrydinyl group, 8-phenanthrydinyl group, 9-phenanthrydinyl group, 10-phenanthrydinyl group, 1-acridinyl group, 2-acridinyl group, 3-acridinyl group, 4-acridinyl group, 9-acridinyl group, 1,7-phenanthrolin-2-yl group, 1,7-phenanthrolin-3-yl group, 1,7-phenanthrolin-4-yl group, 1,7-phenanthrolin-5-yl group, 1,7-phenanthrolin-6-yl group, 1,7-phenanthrolin-8-yl group, 1,7-phenanthrolin-9-yl group, 1,7-phenanthrolin-10-yl group, 1,8-phenanthrolin-2-yl group, 1,8-phenanthrolin-3-yl group, 1,8-phenanthrolin-4-yl group, 1,8-phenanthrolin-5-yl group, 1,8-phenanthrolin-6-yl group, 1,8-phenanthrolin-7-yl group, 1,8-phenanthrolin-9-yl group, 1,8-phenanthrolin-10-yl group, 1,9-phenanthrolin-2-yl group, 1,9-phenanthrolin-3-yl group, 1,9-phenanthrolin-4-yl group, 1,9-phenanthrolin-5-yl group, 1,9-phenanthrolin-6-yl group, 1,9-phenanthrolin-7-yl group, 1,9-phenanthrolin-8-yl group, 1,9-phenanthrolin-10-yl group, 1,10-phenanthrolin-2-yl group, 1,10-phenanthrolin-3-yl group, 1,10-phenanthrolin-4-yl group, 1,10-phenanthrolin-5-yl group, 2,9-phenanthrolin-1-yl group, 2,9-phenanthrolin-3-yl group, 2,9-phenanthrolin-4-yl group, 2,9-phenanthrolin-5-yl group, 2,9-phenanthrolin-6-yl group, 2,9-phenanthrolin-7-yl group, 2,9-phenanthrolin-8-yl group, 2,9-phenanthrolin-10-yl group, 2,8-phenanthrolin-1-yl group, 2,8-phenanthrolin-3-yl group, 2,8-phenanthrolin-4-yl group, 2,8-phenanthrolin-5-yl group, 2,8-phenanthrolin-6-yl group, 2,8-phenanthrolin-7-yl group, 2,8-phenanthrolin-9-yl group, 2,8-phenanthrolin-10-yl group, 2,7-phenanthrolin-1-yl group, 2,7-phenanthrolin-3-yl group, 2,7-phenanthrolin-4-yl group, 2,7-phenanthrolin-5-yl group, 2,7-phenanthrolin-6-yl group, 2,7-phenanthrolin-8-yl group, 2,7-phenanthrolin-9-yl group, 2,7-phenanthrolin-10-yl group, 1-phenoxazinyl group, 2-phenoxazinyl group, 1-phenothiazinyl group, 2-phenothiazinyl group, 3-phenothiazinyl group, 4-phenothiazinyl group, 10-phenothiaznyl group, 1-phenoxazinyl group, 2-phenoxazinyl group, 3-phenoxazinyl group, 4-phenoxazinyl group, 10-phenoxazinyl group, 2-oxazolyl group, 4-oxazolyl group, 5-oxazolyl group, 2-oxadiazolyl group, 5-oxadiazolyl group, 3-furazanyl group, 2-thienyl group, 3-thienyl group, 2-methylpyrrol-1-yl group, 2-methylpyrrol-3-yl group, 2-methylpyrrol-4-yl group, 2-methylpyrrol-5-yl group, 3-methylpyrrol-1-yl group, 3-methylpyrrol-2-yl group, 3-methylpyrrol-4-yl group, 3-methylpyrrol-5-yl group, 2-t-butylpyrrol-4-yl group, 3-(2-phenylpropyl)pyrrol-1-yl group, 2-methyl-1-indolyl group, 4-methyl-1-indolyl group, 2-methyl-3-indolyl group, 4-methyl-3-indolyl group, 2-t-butyl-1-indolyl group, 4-t-butyl-1-indolyl group, 2-t-butyl-3-indolyl group and 4-t-butyl-3-indolyl group. Among these groups, pyridinyl group and quinolyl group are preferable.

Examples of the substituent in the group represented by Cz, M or M′ in the general formulae (1), (2) and (3) include halogen atoms such as a chlorine atom, bromine atom and fluorine atom, carbazole group, hydroxyl group, substituted and unsubstituted amino groups, nitro group, cyano group, silyl group, trifluoromethyl group, carbonyl group, carboxyl group, substituted and unsubstituted alkyl groups, substituted and unsubstituted alkenyl groups, substituted and unsubstituted arylalkyl groups, substituted and unsubstituted aromatic groups, substituted and unsubstituted heteroaromatic heterocyclic groups, substituted and unsubstituted aralkyl groups, substituted and unsubstituted aryloxy groups and substituted and unsubstituted alkyloxyl groups. Among these groups, fluorine atom, methyl group, perfluorophenylene group, phenyl group, naphthyl group, pyridyl group, pyrazyl group, pyrimidyl group, adamantyl group, benzyl group, cyano group and silyl group are preferable.

The bonding mode of the compound represented by the general formula (1) or (2) described above is shown in Table 1 in the following in accordance with the numbers represented by n and m.

TABLE 1

| n = m = 1 | n = 2 | n = 3 | m = 2 | m = 3 |
|---|---|---|---|---|
| Cz—A | Cz—A—Cz | 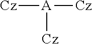 | A—Cz—A | 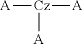 |

The bonding mode of the group represented by the general formula (3) described above is shown in Table 2 in the following in accordance with the numbers represented by p, q and r.

TABLE 2

| No | p | q | r | The bonding mode |
|---|---|---|---|---|
| [1] | 0 | 1 | 1 | L—M′ |
| [2] | 0 | 1 | 2 | L—M′—M′, M′—L—M′ |
| [3] | 0 | 2 | 1 | L—L—M′, L—M′—L |
| [4] | 0 | 2 | 2 | L—L—M′—M′, M′—L—L—M′, |
| | | | | 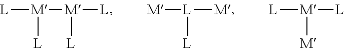 |
| [5] | 1 | 1 | 0 | The same as [1] except that M′ is replaced with M. |
| [6] | 1 | 1 | 1 | M—L—M′ |
| [7] | 1 | 1 | 2 | 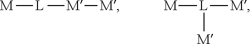 |
| [8] | 1 | 2 | 0 | The same as [3] except that M′ is replaced with M. |
| [9] | 1 | 2 | 1 | M—L—L—M′, L—M—L—M′, M—L—M′—L |
| [10] | 1 | 2 | 2 | M—L—L—M′—M′, M′—L—M—L—M′, M′—M′—L—M—L, |
| | | | | 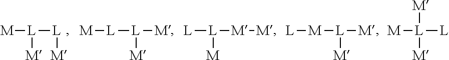 |
| [11] | 2 | 1 | 0 | The same as [2] except that M′ is replaced with M. |
| [12] | 2 | 1 | 1 | The same as [7] except that M′ is replaced with M and M is replaced with M′. |
| [13] | 2 | 1 | 2 | 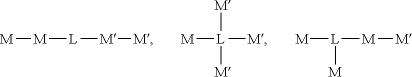 |
| [14] | 2 | 2 | 0 | The same as [4] except that M′ is replaced with M. |
| [15] | 2 | 2 | 1 | The same as [10] except that M′ is replaced with M and M is replaced with M′. |
| [16] | 2 | 2 | 2 | M—M—L—L—M′—M′, |
| | | | | 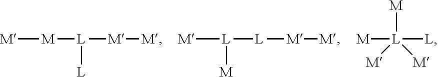 |
| | | | | 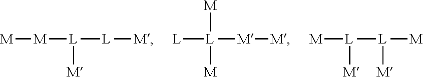 |

The group represented by Cz which is bonded to the group represented by A may be bonded to any of the groups represented by M, L or M′ in the general formula (3) representing the group represented by A.

For example, when the group represented by A has the bonding mode [6] in Table 2 (p=q=r=1) in the compound represented by Cz-A in which m=n=1 in the general formula (1) or (2), the bonding mode includes three bonding modes of Cz-M-L-M′, M-L(Cz)-M′ and M-L-M′-Cz.

When the group represented by A has the bonding mode [7] in Table 2 (p=q=1 and r=2) in the compound represented by Cz-A-Cz in which n=2 in the general formula (1), the bonding mode includes bonding modes shown in the following:

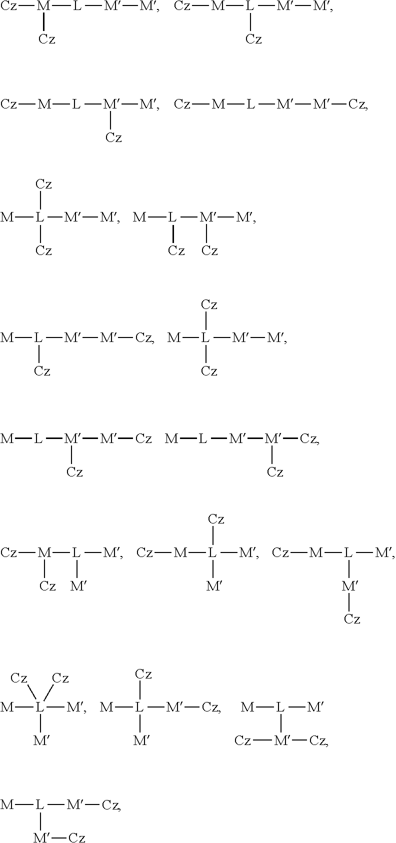

With respect to the bonding mode of the group represented by the general formula (1), (2) or (3) and the combination of the groups shown in the above as the examples, materials for organic EL devices comprising compounds shown in (i) to (iv) in the following are preferable.

(i) Materials for organic EL devices in which n=1 in the general formula (1) and p=1 and r=0 in the general formula (3):

In the general formula (1), Cz represents a substituted or unsubstituted arylcarbazolyl group or carbazolylalkylene group; and in the general formula (3), M represents a heterocyclic six-membered or seven-membered ring having 4 or 5 carbon atoms and nitrogen atom and forming a substituted or unsubstituted ring, a heterocyclic five-membered ring having 2 to 4 carbon atoms and nitrogen atom and forming a substituted or unsubstituted ring, a heterocyclic ring having 8 to 11 carbon atoms and nitrogen atom and forming a substituted or unsubstituted ring or a substituted or unsubstituted imidazopyridinyl(preferably imidazo[1,2-a]pyridinyl) ring, and L represents a substituted or unsubstituted aryl group or arylene group having 6 to 30 carbon atoms or a substituted or unsubstituted heteroaromatic ring having 2 to 30 carbon atoms.

(ii) Materials for organic EL devices in which n=2 in the general formula (1) and p=1 and r=0 in the general formula (3):

In the general formula (1), Cz represents a substituted or unsubstituted arylcarbazolyl group or carbazolylalkylene group; and in the general formula (3), M represents a heterocyclic six-membered or seven-membered ring having 4 or 5 carbon atoms and nitrogen atom and forming a substituted or unsubstituted ring, a heterocyclic five-membered ring having 2 to 4 carbon atoms and nitrogen atom and forming a substituted or unsubstituted ring, a heterocyclic ring having 8 to 11 carbon atoms and nitrogen atom and forming a substituted or unsubstituted ring or a substituted or unsubstituted imidazopyridinyl (preferably imidazo[1,2-a]pyridinyl) ring, and L represents a substituted or unsubstituted aryl group or arylene group having 6 to 30 carbon atoms or a substituted or unsubstituted heteroaromatic ring having 2 to 30 carbon atoms.

(iii) Materials for organic EL devices in which n=1 in the general formula (1) and p=2 and r=0 in the general formula (3):

In the general formula (1), Cz represents a substituted or unsubstituted arylcarbazolyl group or carbazolylalkylene group; and in the general formula (3), M represents a heteroaromatic ring having 2 to 40 carbon atoms and nitrogen atom and forming a substituted or unsubstituted ring, and L represents a substituted or unsubstituted aryl group or arylene group having 6 to 30 carbon atoms or a substituted or unsubstituted heteroaromatic ring having 2 to 30 carbon atoms.

(iv) Materials for organic EL devices in which m=2 in the general formula (2) and p=q=1 in the general formula (3):

In the general formula (2), Cz represents a substituted or unsubstituted arylcarbazolyl group or carbazolylalkylene group; and in the general formula (3), M and M′ each independently represent a heteroaromatic ring having 2 to 40 carbon atoms and nitrogen atom and forming a substituted or unsubstituted ring, and M and M′ may represent a same ring or different rings, and L represents a substituted or unsubstituted aryl group or arylene group having 6 to 30 carbon atoms, a substituted or unsubstituted cycloalkylene group having 5 to 30 carbon atoms or a substituted or unsubstituted heteroaromatic ring having 2 to 30 carbon atoms.

In the above general formulae (1) and (2), it is preferable that Cz represents a substituted or unsubstituted arylcarbazolyl group and, more preferably, phenylcarbazolyl group. It is preferable that the aryl portion of the arylcarbazolyl group is substituted with a carbazolyl group.

It is preferable that the energy gap of the triplet state of a compound represented by the general formula (1) or (2) is 2.5 to 3.3 eV and more preferably 2.5 to 3.2 eV.

It is preferable that the energy gap of the singlet state of a compound represented by the general formula (1) or (2) is 2.8 to 3.8 eV and more preferably 2.9 to 3.7 eV.

The triplet energy gap and the singlet energy gap of a compound may be measured in accordance with the following methods:

### (1) Measurement of the Triplet Energy Gap

The lowest excited triplet energy level is measured. The phosphorescence spectrum of a sample is measured (10 μmoles/liter; an EPA (diethyl ether:isopentane:ethanol=5:5:2 by volume) solution; 77K; a quartz cell; FLUOROLOG II manufactured by SPEX Company). A tangent is drawn to the increasing line at the short wavelength side of the phosphorescence spectrum and the wavelength at the intersection of the tangent and the abscissa (the end of light emission) is obtained. The obtained wavelength is converted into the energy.

### (2) Measurement of the Singlet Energy Gap

The excited singlet energy gap is measured. Using a toluene solution (10⁻⁵ moles/liter) of a sample, the absorption spectrum is obtained by a spectrometer for absorption of ultraviolet and visible light manufactured by HITACHI Co. Ltd. A tangent is drawn to the increasing line at the long wavelength side of the spectrum and the wavelength at the intersection of the tangent and the abscissa (the end of absorption) is obtained. The obtained wavelength is converted into the energy.

Synthesis of host materials is as follows:

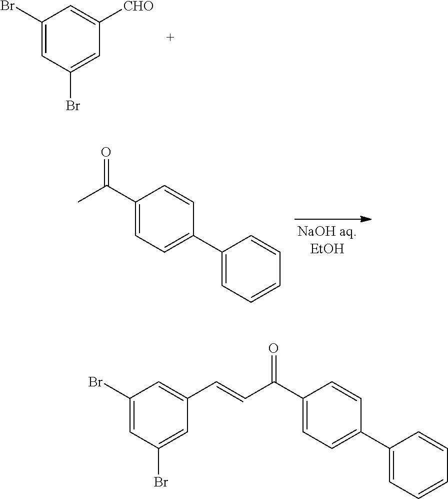 [SMILES: O=Cc1cc(Br)cc(Br)c1 ; CC(=O)c1ccc(-c2ccccc2)cc1 ; O=C(/C=C/c1cc(Br)cc(Br)c1)c1ccc(-c2ccccc2)cc1]

Into 1300 ml of ethanol, 50.8 g (192 mmol) of 3,5-dibromobenzaldehyde and 37.8 g (192 mmol) of 4-acetylbiphenyl were added. The mixture was stirred at room temperature and then an aqueous solution of 14.2 g (356 mmol, 185 mol %) of sodium hydroxide in 70 ml of water was gradually dropped into the reaction solution. After stirring for 7 h at room temperature, the reaction solution was allowed to stand overnight. The precipitate was collected by filtration, dispersed in water and then ethanol for washing, and vacuum-dried, to obtain 82.9 g (99% yield) of the aimed chalcone compound as a pale yellow solid.

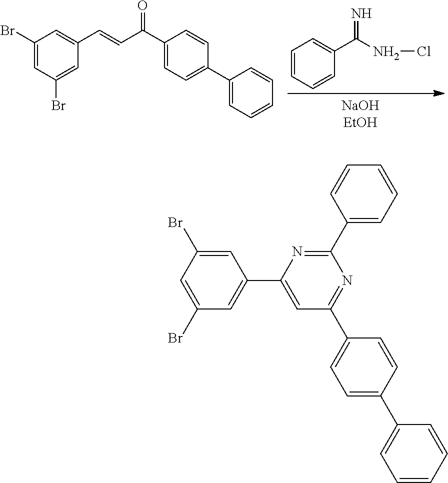

Into 1000 ml of ethanol, 82.9 g (187 mmol) of the chalcone compound synthesized above and 30.2 g (193 mmol, 103 mol %) of benzamidine hydrochloride were added. The mixture was stirred at room temperature and then 15.0 g (374 mmol, 200 mol %) of sodium hydroxide was gradually added to the reaction liquid in several small portions. Thereafter, the reaction liquid was heated to the reflux temperature and stirred for 8 hours and then allowed to stand overnight. The precipitate was collected by filtration, washed with water and then methanol, and vacuum-dried, to obtain 46.3 g (45% yield) of the aimed pyrimidine compound as a white solid.

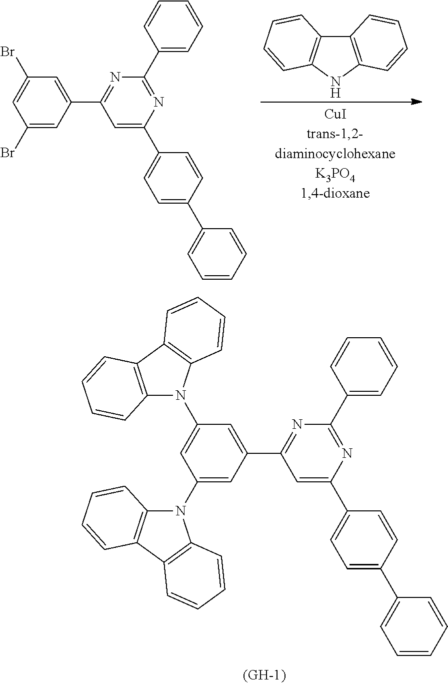

Into a 1000-ml flask, 46.2 g (85.2 mmol) of the pyrimidine compound synthesized above, 34.2 g (204 mmol, 240 mol %) of carbazole, 1.6 g (8.5 mmol, 10 mol %) of copper iodide, and 54.3 g (256 mmol, 300 mol %) of tripotassium phosphate were charged. After replacing the inner atmosphere with Ar gas, 300 ml of dry 1,4-dioxane was added to the flask. The temperature was raised to 70° C. and the contents were stirred. Then, the reaction liquid was added with 1.9 g (17.4 mmol, 20 mol %) of trans-1,2-cyclohexanediamine and heated to the reflux temperature. After 5 hours, the reaction liquid was added with 1.6 g (8.5 mmol, 10 mol %) of copper iodide, 1.0 g (8.7 mmol, 10 mol %) of trans-1,2-cyclohexanediamine, and 18.1 g (85 mmol, 100 mol %) of tripotassium phosphate and stirred for 10 h at the reflux temperature. The reaction liquid was concentrated, the precipitated solid was dissolved in toluene, and the insolubles were removed by filtration. The collected filtrate was concentrated under reduced pressure. The precipitated solid was recrystallized twice from toluene, to obtain 37.7 g (62% yield) of the preferred host material as a white solid.

### EXAMPLES

The invention will be described in further detail with reference to the following examples and comparative examples. However, the invention is not limited by the following examples.

### Manufacturing of Organic EL Device

### Example 1

A glass substrate (size: 25 mm×75 mm×1.1 mm) having an ITO transparent electrode (manufactured by Geomatec Co., Ltd.) was ultrasonic-cleaned in isopropyl alcohol for five minutes, and then UV (Ultraviolet)/ozone-cleaned for 30 minutes.

After the glass substrate having the transparent electrode was cleaned, the glass substrate was mounted on a substrate holder of a vacuum deposition apparatus. A hole transporting (HT) layer was initially formed by vapor-depositing a 40-nm thick HT-1 and 20-nm thick HT-2 to cover the surface of the glass substrate where the transparent electrode lines were provided.

A green phosphorescent-emitting layer was obtained by co-depositing GH-1 as a green phosphorescent host and GD-1 as a green phosphorescent dopant onto the hole transporting layer in a thickness of 40 nm. The concentration of GD-1 was 15 wt %.

Then, a 40-nm-thick electron transporting (ET-1) layer, a 1-nm-thick LiF layer and a 80-nm-thick metal Al layer were sequentially formed to obtain a cathode. A LiF layer, which was an electron injectable electrode, was formed at a speed of 1 Å/sec.

### Comparative Example 1

An organic EL device was prepared in the same manner as Example 1 except that CBP (4,4′-bis(N-carbazolyl)biphenyl) was used instead of GH-1 as the green phosphorescent host and Ir(ppy)₃ was used instead of GD-1 as the green phosphorescent dopant.

### Comparative Example 2

An organic EL device was prepared in the same manner as Example 1 except that Ir(ppy)₃ was used instead of GD-1 as the green phosphorescent dopant.

### Comparative Example 3

An organic EL device was prepared in the same manner as Example 1 except that CBP was used instead of GH-1 as the green phosphorescent host.

Structures of the devices according to Example 1 and Comparative Examples 1 to 3 are shown in Table 1.

TABLE 1

| | Hole | Green | Electron |
|---|---|---|---|
| | Transporting | Phosphorescent | Transporting |
| | Layer | Emitting Layer | Layer |
| Example 1 | HT-1/HT-2 | 15% GD-1 | ET-1 |
| | | GH-1 | |
| Comparative | HT-1/HT-2 | 15% Ir(ppy)3 | ET-1 |
| Example 1 | | CBP | |
| Comparative | HT-1/HT-2 | 15% Ir(ppy)3 | ET-1 |
| Example 2 | | GH-1 | |
| Comparative | HT-1/HT-2 | 15% GD-1 | ET-1 |
| Example 3 | | CBP | |

HT-1 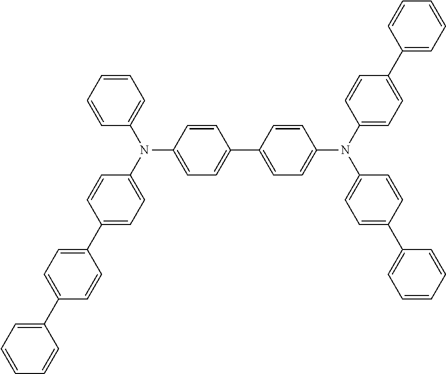 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1] HT-2 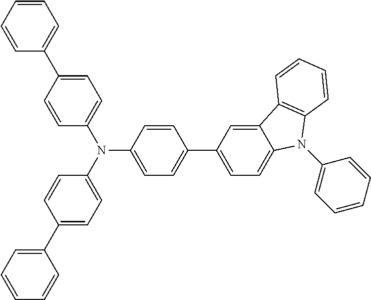 [SMILES: c1ccc(-c2ccc(N(c3ccc(-c4ccccc4)cc3)c3ccc(-c4ccc5c(c4)c4ccccc4n5-c4ccccc4)cc3)cc2)cc1] ET-1

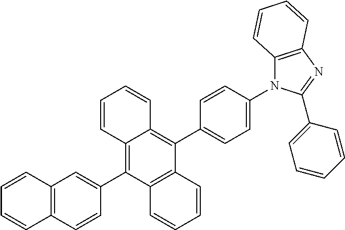 [SMILES: c1ccc(-c2nc3ccccc3n2-c2ccc(-c3c4ccccc4c(-c4ccc5ccccc5c4)c4ccccc34)cc2)cc1]

Evaluation of Organic EL Device

The organic EL devices each manufactured in Example 1 and Comparative Examples 1 to 3 were driven by direct-current electricity of 1 mA/cm² to emit light, to measure the emission chromaticity, the luminescence (L) and the voltage. Using the measured values, the current efficiency (L/J) and the luminance efficiency η(lm/W) were obtained.

The results are shown in Table 2.

TABLE 2

| | | | | Current | Luminous | Chromaticity | | LT80 | LT50 |
|---|---|---|---|---|---|---|---|---|---|
| | | | Voltage | Efficiency | Efficiency | (CIE Color system) | | @20,000 cd/m² | @20,000 cd/m² |
| emitter | host | | (V) | (cd/A) | (lm/W) | x | y | (hrs) | (hrs) |
| GD-1 | GH-1 | Example 1 | 3.08 | 70.0 | 71.5 | 0.336 | 0.624 | 80 | 540 |
| Ir(ppy)3 | CBP | Comparative | 4.29 | 9.0 | 6.6 | 0.293 | 0.635 | 15 | 80 |
| | | Example 1 | | | | | | | |
| Ir(ppy)3 | GH-1 | Comparative | 3.45 | 66.8 | 60.9 | 0.329 | 0.623 | 30 | 300 |
| | | Example 2 | | | | | | | |
| GD-1 | CBP | Comparative | 3.90 | 12.8 | 10.3 | 0.313 | 0.635 | 50 | 250 |
| | | Example 3 | | | | | | | |

As is clear from Table 2, the organic EL device according to Example 1 exhibited excellent luminous efficiency and long lifetime as compared with the organic EL devices according to Comparative Examples 1 to 3.

What is claimed is:

1. An organic light emitting device comprising an anode, a cathode and an emissive layer, wherein the emissive layer is located between the anode and the cathode, and the emissive layer comprises a host material and a phosphorescent emitter material, wherein:
(a) the host material comprises a substituted or unsubstituted hydrocarbon compound having the chemical structure represented by formula (1) or (2):
(Cz-)ₙA (1)
Cz(-A)ₘ (2)
wherein Cz is a substituted or unsubstituted arylcarbazolyl group or carbazolylalkylene group, A is a group represented by following general formula (3):
(M)ₚ-(L)_{q}-(M′)ᵣ (3)
wherein M and M′ are each independently a heteroaromatic ring having 2 to 40 carbon atoms and a nitrogen atom and forming a substituted or unsubstituted ring, M and M′ may represent a same ring or different rings, L is a single bond, a substituted or unsubstituted aryl group or arylene group having 6 to 30 carbon atoms, a substituted or unsubstituted cycloalkylene group having 5 to 30 carbon atoms or a substituted or unsubstituted heteroaromatic ring having 2 to 30 carbon atoms, p is 0 to 2, q is 1 or 2, r is 0 to 2, and p+r represents an integer of 1 or greater; and n and m are 1 to 3; and
(b) the phosphorescent emitter material comprises a phosphorescent organometallic complex having a substituted chemical structure represented by one of the following partial chemical structures of the formula:
LL′L″M
wherein M is a metal that forms octahedral complexes, L, L′, L″ are equivalent or inequivalent bidentate ligands wherein each L comprises a substituted or unsubstituted phenylpyridine ligand coordinated to M through an sp² hybridized carbon and N; and
one of L, L′ and L″ is inequivalent to at least one of the other two.

2. The organic light emitting device of claim 1, wherein the host material has the chemical structure represented by the formula:

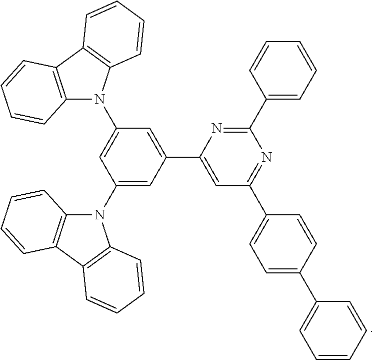 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

3. The organic light emitting device of claim 1, wherein the triplet energy of the host material is from about 2.0 eV to about 2.8 eV.

4. The organic light emitting device of claim 1, wherein the phosphorescent emitter material comprises a phosphorescent organometallic complex wherein the substituted chemical structure is substituted with at least two methyl groups.

5. The organic light emitting device of claim 1, wherein the phosphorescent emitter material comprises a phosphorescent organometallic compound having a substituted chemical structure represented by the following chemical structure: 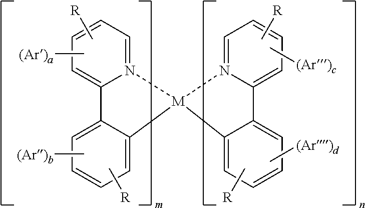
where each R is independently selected from the group consisting of H, alkyl, alkenyl, alkynyl, alkylaryl, CN, CF₃, CₙF₂ₙ₊₁, trifluorovinyl, CO₂R, C(O)R, NR₂, NO₂, OR, halo, aryl, heteroaryl, substituted aryl, substituted heteroaryl or a heterocylic group;
Ar′, Ar″, Ar′″ and Ar″″ each independently represent a substituted or unsubstituted aryl or heteroaryl unfused substituent on the phenylpyridine ligand;
a is 0 or 1;
b is 0 or 1;
c is 0 or 1;
d is 0 or 1;
m is 1 or 2;
n is 1 or 2;
m+n is the maximum number of ligands that can be coordinated to M; and
wherein at least one of a, b, c, and d is 1 and when at least one of a and b is 1 and at least one of b and c is 1, at least one of Ar′ and Ar″ is different from at least one of Ar′″ and Ar″″.

6. The organic light emitting device of claim 1, wherein the phosphorescent emitter material comprises a metal complex, and the metal complex comprises a metal atom selected from Ir, Pt, Os, Au, Cu, Re, Ru and a ligand.

7. The organic light emitting device of claim 6, wherein the metal complex has an ortho-metal bond.

8. The organic light emitting device of claim 7, wherein the metal atom is Ir.

9. The organic light emitting device of claim 1, wherein the phosphorescent emitter material comprises a phosphorescent organometallic complex having a substituted chemical structure represented by the following partial chemical structure:

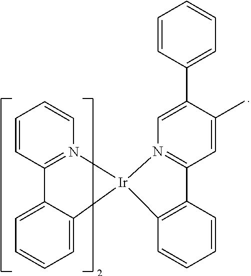

10. The organic light emitting device of claim 1, wherein the host material comprises an unsubstituted aromatic hydrocarbon compound having the chemical structure represented by the formula: 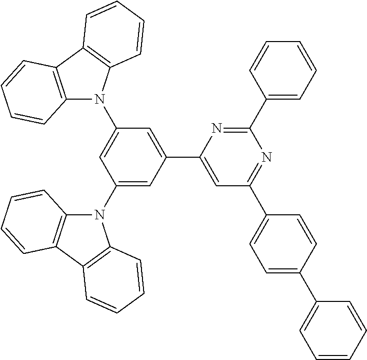 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]
and wherein the phosphorescent emitter material comprises a phosphorescent organometallic compound having a substituted chemical structure represented by the following chemical structure: 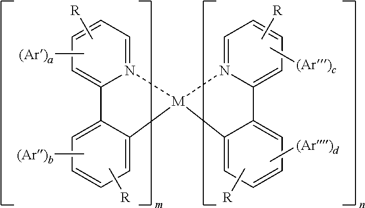
where each R is independently selected from the group consisting of H, alkyl, alkenyl, alkynyl, alkylaryl, CN, CF₃, CₙF₂ₙ₊₁, trifluorovinyl, CO₂R, C(O)R, NR₂, NO₂, OR, halo, aryl, heteroaryl, substituted aryl, substituted heteroaryl or a heterocylic group;
Ar′, Ar″, Ar′″ and Ar″″ each independently represent a substituted or unsubstituted aryl or heteroaryl unfused substituent on the phenylpyridine ligand;
a is 0 or 1;
b is 0 or 1;
c is 0 or 1;
d is 0 or 1;
m is 1 or 2;
n is 1 or 2;
m+n is the maximum number of ligands that can be coordinated to M; and
wherein at least one of a, b, c, and d is 1 and when at least one of a and b is 1 and at least one of b and c is 1, at least one of Ar′ and Ar″ is different from at least one of Ar′″ and Ar″″.

11. The organic light emitting device of claim 10, wherein at least one of the phosphorescent materials contained in the light emitting layer has a maximum value of 500 nm or more and 720 nm or less in a light emitting wavelength.
